(19) United States
(12) Patent Application Publication
(10) Pub. No.: US 2005/0133808 A1
(43) Pub. Date: Jun. 23, 2005

(54) Package for housing light-emitting element, light-emitting apparatus and illumination apparatus

(75) Inventors: Mitsugu Uraya, Gamo-gun (JP); Daisuke Sakumoto, Gamo-gun (JP); Akira Miyake, Gamo-gun (JP); Fumiaki Sekine, Gamo-gun (JP); Yuki Mori, Gamo-gun (JP); Mitsuo Yanagisawa, Gamo-gun (JP); Hiroshi Shibayama, Gamo-gun (JP); Shingo Matsuura, Gamo-gun (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 10/978,302

(22) Filed: Oct. 29, 2004

(30) Foreign Application Priority Data
Nov. 26, 2003 (JP) P2003-396426
Mar. 12, 2004 (JP) P2004-71427
Dec. 19, 2003 (JP) P2003-423439
Mar. 12, 2004 (JP) P2004-71428
Sep. 22, 2004 (JP) P2004-275058
Sep. 11, 2003 (JP) P2003-320240
Dec. 25, 2003 (JP) P2003-429420
Mar. 12, 2004 (JP) P2004-71429
Oct. 30, 2003 (JP) P2003-369952
Mar. 12, 2004 (JP) P2004-71430
Nov. 27, 2003 (JP) P2003-397232
Mar. 12, 2004 (JP) P2004-71433
Dec. 24, 2003 (JP) P2003-428250
Mar. 12, 2004 (JP) P2004-71434

(51) Int. Cl. H01L 33/00

(52) U.S. Cl. 257/99

(57) ABSTRACT

A light-emitting apparatus provides a ceramic-made base body, a frame body, a light-emitting element, a conductor layer and a light-transmitting member. The base body has on its upper surface a mounting portion for the light-emitting element. The frame body is joined to the upper surface of the base body so as to surround the mounting portion, with its inner peripheral surface shaped into a reflection surface. The wiring conductor has its one end formed on the upper surface of the base body and electrically connected to the light-emitting element, and has another end led to a side or lower surface of the base body. The light-transmitting member is disposed inside the frame body so as to cover the light-emitting element, which contains fluorescent materials for performing wavelength conversion. The base body is so designed that ceramic crystal grains range in average particle diameter from 1 to 5 μm.

### BACKGROUND OF THE INVENTION

1. Field of the Invention

The present invention relates to a package for housing a light-emitting element; a light-emitting apparatus; and an illumination apparatus, in particular, to a package for housing a light-emitting element; a light-emitting apparatus; and an illumination apparatus which allow light emitted from a light-emitting element and wavelength-converted by fluorescent materials to radiate out.

2. Description of the Related Art

FIG. 31 shows a light-emitting apparatus 11 according to a first related art in which light such as near-ultraviolet light of blue-color light emitted from a light-emitting element 14, for example a light emitting diode (LED), is wavelength-converted by a plurality of fluorescent materials (not shown) which are excited by the light emitted from the light-emitting element and generate fluorescence of different colors such as red, green, blue, and yellow, so as to be emitted therefrom as white-color light. In FIG. 31, the light-emitting apparatus 11 is mainly composed of a base body 12 made of an insulating material; a frame-like frame body 13; a light-transmitting member 15; and a light-emitting element 14. The base body 12 has, at the center of its upper surface, a mounting portion 12a for mounting thereon the light-emitting element 14. The base body 12 also has a wiring conductor (not shown) formed of a lead terminal, a metallized wiring line, or the like for electrically conductively connecting within and without the light-emitting apparatus in and around the mounting portion 12a. The frame body 13 fixedly bonded to the upper surface of the base body 12 has a through hole 13a formed such that its upper opening is larger than its lower opening. Moreover, the frame body 13 has its inner peripheral surface shaped into a reflection surface 13b for reflecting light emitted from the light-emitting element 14. The light-transmitting member 15 is charged inside the frame body 13 and contains fluorescent materials which are excited by the light emitted from the light-emitting element 14 for effecting wavelength conversion. The light-emitting element 14 is fixedly mounted on the mounting portion 12a.

FIG. 32 shows a package for housing a light-emitting element 25 such as a light-emitting diode (LED) according to a second related art. In FIG. 32, the package for housing the light-emitting element is mainly composed of a base body 21 and a frame-like reflection member 22. The base body 21 has, at the center of its upper surface, a mounting portion 21a for mounting thereon the light-emitting element 25, and also has a conductor layer 27 formed of a lead terminal, a metallized wiring line, or the like so as to extend from the mounting portion 21a to the outer surface of the base body 21, for electrically conductively connecting within and without the light-emitting element storage package. The reflection member 22 is fixedly bonded to the upper surface of the base body 21, and has a through hole 22a formed such that its upper opening is larger than its lower opening. Moreover, the reflection member 22 has its inner peripheral surface shaped into a reflection surface 22b for reflecting light emitted from the light-emitting element 25.

Firstly, the light-emitting element 25 is mounted on the mounting portion 21a of the package for housing the light-emitting element. Then, an electrode 26 of the light-emitting element 25 is electrically connected to the conductor layer 27. Lastly, the light-transmitting member 13, which contains fluorescent materials for effecting long-wavelength conversion through excitation of the light emitted from the light-emitting element 25, is charged inside the reflection member 22 so as to cover the light-emitting element 25. Whereupon, the light emitting apparatus 20 is realized.

In the light-emitting apparatus 20, the light emitted from the light-emitting element 25 such as near-ultraviolet light or blue-color light is wavelength-converted by a plurality of fluorescent materials of different colors such as red, green, blue, and yellow contained in the light-transmitting member 13, so as to be emitted therefrom as white-color light.

FIG. 33 shows a light-emitting apparatus 30 according to a third related art in which light such as near-ultraviolet light or blue-color light emitted from a light-emitting element 14, for example a light-emitting diode (LED), is wavelength-converted by a plurality of fluorescent materials (not shown) of different colors such as red, green, blue, and yellow, so as to be emitted therefrom as white-color light. In FIG. 33, the light-emitting apparatus 30 is mainly composed of a base body 31 made of an insulating material; a frame-like frame body 32; a light-transmitting resin 33; and a light-emitting element 35. The base body 31 has, at the center of its upper surface, a mounting portion 31a for mounting thereon the light-emitting element 35. The base body 31 also has a wiring conductor (not shown) formed of a lead terminal, a metallized wiring line, or the like for electrically conductively connecting within and without the light-emitting apparatus on and around the mounting portion 31a. The reflection member 32 is fixedly bonded to the upper surface of the base body 31, and has a through hole 32a formed such that its upper opening is larger than its lower opening. Moreover, the reflection member 32 has its inner peripheral surface shaped into a reflection surface 32b for reflecting light emitted from the light-emitting element 35. The light-transmitting resin 33 is charged inside the reflection member 32, and contains fluorescent materials 34 which are excited by the light emitted from the light-emitting element 35 for effecting wavelength conversion. The light-emitting element 35 is fixedly mounted on the mounting portion 31a.

The base body 12, 21, 31 is made of ceramics such as aluminum oxide sintered body (alumina ceramics), aluminum nitride sintered body, mullite sintered body, or glass ceramics, or a resin material such as epoxy resin. In a case where the base body 12, 21, 31 is made of ceramics, on the upper surface thereof is formed a wiring conductor by firing a metal paste of tungsten (W) or molybdenum manganese (Mo—Mn) at a high temperature. On the other hand, in a case where the base body 12, 21, 31 is made of a resin material, a lead terminal made of copper (Cu), an iron (Fe)-nickel (Ni) alloy, or the like material is fixedly arranged within the base body 12, 21, 31 by molding.

Moreover, the frame body 13 and the reflection member 22, 32 have a through hole 13a, 22a, 32d formed such that its upper opening is larger than its lower opening, and also has a reflection surface 13b, 22b, 32b formed on its inner peripheral surface for reflecting light. Specifically, the frame body 13 and the reflection member 22, 32 are formed of a metal material such as aluminum (Al) or an Fe—Ni-cobalt (Co) alloy, or ceramics such as alumina ceramics, or a resin material such as epoxy resin, through a cutting process or a molding technique such as die molding or extrusion.

Further, the reflection surface 13b, 22b, 32b of the frame body 13 and the reflection member 22, 32 are formed by polishing and flattening the inner peripheral surface of the through hole 13a, 22a, 32a, or formed by coating the inner peripheral surface of the through hole 13a, 22a, 32a with a metal such as Al by means of vapor deposition or plating, to be capable of reflecting light emitted from the light-emitting element 14, 25, 35 effectively. The frame body 13 and the reflection member 22, 32 are joined to the upper surface of the base body 12, 21, 31, with use of solder, a brazing filler material such as silver (Ag) brazing filler, or a resin adhesive, in such a way that the mounting portion 12a, 21a, 31a are surrounded by the inner peripheral surface of the frame body 13 and the reflection member 22, 32.

In the first and third related arts, firstly, the wiring conductor arranged near the mounting portion 12a, 31a is electrically connected to the light-emitting element 14, 35 through electrical connecting means (not shown) and an electrode 36 such as a bonding wire or a metal ball. Then, the light-transmitting member 15 and the light-transmitting resin 33 such as epoxy resin or silicone resin containing fluorescent material is charged inside the frame body 13 and the reflection member 32 by an injector such as a dispenser so as to cover the light-emitting element 14 and 35. Lastly, the charged light-transmitting member is cured with heat in an oven. Whereupon, there is realized the light-emitting apparatus 11 and 30 capable of taking out light having a desired wavelength spectrum by subjecting the light emitted from the light-emitting element 14 and 35 to wavelength conversion effected by the fluorescent materials.

In the second related art, the light-emitting element 25 is electrically connected to the conductor layer 27 arranged on the mounting portion 21a through an electrode 26 disposed on a lower surface of the light-emitting element 25. The electrode 26 of the light-emitting element 25 and the conductor layer 27 are joined to each other with use of a conductive adhesive 28 such as solder, an Ag paste (resin containing Ag particles) or the like.

The light-transmitting member 23 is made of light-transmitting resin such as epoxy resin or silicone resin containing fluorescent materials, and is formed by charging the light-transmitting resin inside the reflection member 22 by an injector such as a dispenser so as to cover the light-emitting element 25 and then curing the charged light-transmitting member with heat in an oven. Whereupon, it is possible to take out light having a desired wavelength spectrum by subjecting the light emitted from the light-emitting element 25 to wavelength conversion effected by the fluorescent materials.

This light-emitting apparatus 30 is driven to activate the light-emitting element 25 with a current voltage fed from an external electric circuit (not shown), and thereby visible light is emitted from the light-emitting apparatus. The light-emitting apparatus will find a wider range of applications including indicators of various types; an optical sensor; a display; a photocoupler; a back-light source; and an optical print head.

In recent years, such light-emitting apparatuses as shown hereinabove have been coming into wider and wider use as illumination apparatuses. This trend has created an increasing demand for a more sophisticated light-emitting apparatus that is excellent in radiation intensity and heat-dissipation property. In addition, as is often the case with a light-emitting apparatus employing a light-emitting element, improvement in service life has been expected.

As to the related art, there is Japanese Unexamined Patent Publication JP-A 2003-37298 (2003).

In the light emitting apparatus 11 according to the first related art shown in FIG. 31, in order to allow the light emitted from the light-emitting element 14 to radiate out of the light-emitting apparatus 11 with high efficiency, for example, the upper surface of the base body 12 made of ceramics is flattened through a polishing process, or the upper surface of the base body 12 is coated with a film of a metal such as Al or Au, so as to improve the reflectivity of the upper surface of the base body 12. However, in the light-emitting apparatus 11 in which the light emitted from the light-emitting element 14 is wavelength-converted by fluorescent materials contained within the light-transmitting member 15, the light emitted from the light-emitting element 14 is transmitted through the light-transmitting member 15 and is then specularly reflected from the upper surface of the base body 12. In this case, the fluorescent materials other than fluorescent materials present in a specular reflection direction cannot be excited readily. That is, wavelength conversion is effected mainly by a part of the fluorescent materials, which leads to poor wavelength conversion efficiency. This gives rise to a problem of optical power, brightness, and color rendering being deteriorated.

Moreover, in a case where the base body 12 is made of ceramics, light is absorbed by the substrate 12, and thus the reflectivity of the upper surface of the base body 12 tends to decrease. As a result, the light-emitting apparatus fails to provide desired optical power, as well as recently-demanded satisfactory light takeoff efficiency. Further, in a case where the base body 12 has its upper surface coated with a metal film to prevent light absorption on the substrate 12, the metal film needs to be formed by means of plating or vapor deposition, which leads to an undesirable increase in the manufacturing process steps and manufacturing cost.

On the other hand, in a case where the base body 12 is made of a resin material such as epoxy resin or liquid crystal polymer, heat emanating from the light-emitting element 14 cannot be dissipated to the outside through the base body 12 with high efficiency. The remaining heat thus causes significant degradation of the light-emitting efficiency of the light-emitting element 14. As a result, the optical power of the light-emitting apparatus 11 is decreased.

Moreover, in the light-transmitting member 15 that covers the light-emitting element 14 and contains fluorescent materials for performing wavelength conversion on the light emitted from the light-emitting element 14, when the fluorescent material content is increased to improve the wavelength conversion efficiency, the light radiating out of the light-emitting apparatus will be prone to being disturbed by the fluorescent materials. This makes it impossible to enhance the optical power. By contrast, when the fluorescent material content is reduced, the wavelength conversion efficiency will be decreased, and thus light having a desired wavelength cannot be obtained. As a result, enhancement of the optical power becomes impossible.

In the light emitting apparatus 20 according to the second related art shown in FIG. 32, however, at the time when the light-emitting element 25 is fixedly bonded to the conductor layer 27 of the mounting portion 21a, for example, the conductive adhesive 28 in use may extend out of the conductor layer 27 and thus incur variation in thickness. In this case, the light-emitting element 25 may be bonded in an inclined state. When the light-emitting element 25 is mounted on the mounting portion 21a in an inclined state, it will be difficult to allow the light emitted from the light emitting element 25 to be reflected from the reflection member 22 at a desired radiation angle so as to radiate out satisfactorily. This gives rise to a problem of the radiation intensity of the light omitted from the light-emitting apparatus being lower.

Moreover, variation in the thickness of the conductive adhesive 20 used for fixedly bonding the light-emitting element 25 onto the conductor layer 27 makes it difficult to allow the heat emanating from the light-emitting element 25 to be dissipated, through the conductive adhesive 28 and the base body 21, to the outside with high efficiency. As a result, the light-emitting element 25 undergoes temperature rise, and thus the radiation intensity of the light emitted from the light-emitting element 25 tends to decrease. This gives rise to a problem that the radiation intensity of the light emitted from the light-emitting apparatus cannot be maintained with stability.

Further, the conductive adhesive 28 used for joining together the conductor layer 27 and the light-emitting element 25 flows outwardly of the outer periphery of the light-emitting element 25 so as to cover the upper surface of the base body 21. In this case, the light emitted from the light-emitting element 25 and the fluorescent materials is prone to being absorbed by the flowing conductive adhesive 28. This gives rise to a problem of the radiation intensity, brightness, and color rendering of the light emitted from the light-emitting apparatus being deteriorated.

Moreover, since the conductive adhesive 28 for joining together the conductor layer 27 and the light-emitting element 25 is exposed off the area between the mounting portion 21a and the light-emitting element 25, it follows that the light emitted from the light-emitting element 25 and the fluorescent materials is applied to the conductive adhesive 28. The light applied to the conductive adhesive 28 is prone to being partly absorbed by the conductive adhesive 28. This gives rise to a problem of the radiation intensity, brightness, and color rendering of the light omitted from the light-emitting apparatus being deteriorated.

Further, in a case where the light emitted from the light-emitting element 25 is ultraviolet light, when the emitted light is applied to the conductive adhesive 28, the conductive adhesive 28 suffers from quality degradation. This causes the bonding strength between the conductor layer 27 and the light-emitting element 25 to decrease, which may result in difficulty in maintaining the steadfast fixation between the conductor layer 27 and the light-emitting element 25 for a longer period of time. As a result, inconveniently, there arises a problem such as a break between the electrode 26 of the light-emitting element 25 and the conductor layer 27. This makes it difficult to achieve a longer service life in the light emitting apparatus.

In addition, in recent years, further increase in radiation intensity has been demanded of a light-emitting apparatus. However, in the light-emitting apparatus 30 according to the third related art, when the amperage of a current inputted to the light-emitting element 35 is increased to enhance the radiation light intensity, the light emission intensity of the light-emitting element 35 does not improve in proportion to the amperage of the current and will thus tend to vary. This makes it impossible to obtain stable radiation intensity.

In detail, when the amperage of a current inputted to the light-emitting element 35 is increased to enhance the radiation light intensity, a junction temperature of the light-emitting element 35 is increased, with the result that light emission efficiency is remarkably deteriorated. This gives rise to a problem that the radiation intensity which is proportional to an input current cannot be obtained. Also, this gives rise to a problem that stable radiation intensity cannot be obtained due to variation in light emission wavelength which is predicted to be due to heat.

Moreover, in the light transmitting resin 33 that covers the light-emitting element 35 and contains the fluorescent materials 34 for performing wavelength conversion on the light emitted from the light-emitting element 35, if the fluorescent material 34 content is increased to improve the wavelength conversion efficiency, light which is wave length-converted by the fluorescent materials 34 will be prone to being disturbed by the other fluorescent materials. This makes it impossible to enhance the radiation intensity.

By contrast, if the fluorescent material 34 content is reduced, the wavelength conversion efficiency will be decreased, and thus light having a desired wavelength cannot be obtained. As a result, enhancement of the radiation intensity becomes impossible.

Further, heat emanating from the light-emitting element 35 is easily transmitted through the base body 31 to the reflection member 32. Thus, the reflection member 32 is thermally expanded and resultantly deformed due to the difference in thermal expansion between the reflection member 32 and the base body 31. This gives rise to problems of the radiation angle being varied and the radiation intensity being lowered.

### SUMMARY OF THE INVENTION

The invention has been devised in view of the above described problems with the related art, and accordingly its object is to provide a package for housing a light-emitting element storage, a light-emitting apparatus and a illumination apparatus that have succeeded in providing excellent illumination characteristics such as on-axis luminous intensity, brightness and color rendering, by improving the efficiency of wavelength conversion effected by fluorescent materials to enhance the optical power of the light-emitting apparatus, and by allowing light emitted from a light-emitting element to radiate out efficiently.

Another object of the invention is to provide a package for housing a light-emitting element, a light-emitting apparatus and a illumination apparatus that has succeeded in maintaining desired radiation characteristics for a longer period of time with stability by dissipating heat emanating from the light-emitting element successfully.

The invention provides a package for housing a light-emitting element comprising:

a base body made of ceramics and having, on its upper surface, a mounting portion for mounting thereon a light-emitting element;

a frame body joined to an outer periphery of the upper surface of the base body so as to surround the mounting portion, an inner peripheral surface of which frame body is shaped into a reflection surface for reflecting light emitted from the light-emitting element; and

a wiring conductor having its one end formed on the upper surface of the base body so as to be electrically connected to an electrode of the light-emitting element, and another end led out to a side or lower surface of the base body,

wherein the base body is so designed that crystal grains contained in the ceramics range in average particle diameter from 1 to 5 μm.

The invention provides a light-emitting apparatus comprising:

the package an set forth hereinabove; and

a light-emitting element mounted on the mounting portion and electrically connected to the wiring conductor.

In the invention, the light-emitting apparatus further comprises a light-transmitting member disposed inside the frame body so as to cover the light-emitting element, which contains fluorescent materials for performing wavelength conversion on light emitted from the light-emitting element.

In the invention, an interval between an upper surface of the light-transmitting member and an active layer of the light-emitting element is kept in a range from 0.1 to 0.8 mm.

In the invention, the one end of the wiring conductor is designed as a conductor layer to which the light-emitting element is electrically connected through a conductive adhesive, and a convexity made of an insulating material is formed around the conductor layer.

In the invention, the conductor layer is so configured that the conductor layer lies inwardly of an outer periphery of the light-emitting element.

In the invention, the convexity is so shaped that its side surface inclinedly extend outward gradually with increasing proximity to the base body.

In the invention, the one end of the wiring conductor is designed as a conductor layer to which the light-emitting element is electrically connected through a conductive adhesive, and a convexity is formed in a part of an upper surface of the conductor layer which part lies inwardly of an outer periphery of the light-emitting element.

In the invention, the mounting portion protrudes from the upper surface of the base body.

In the invention, the protruding mounting portion is so shaped that its side surfaces inclinedly extend outward gradually with increasing proximity to the base body.

In the invention, the mounting portion from the upper surface of the base body, an active layer of the light-emitting element is higher in level than a lower end of the reflection surface, and the light-transmitting member is so disposed that an interval between its upper surface and the light-emitting section is kept in a range from 0.1 to 0.5 mm.

In the invention, the light-transmitting member is so designed that its center portion it larger in arithmetic average surface roughness than its outer peripheral portion.

In the invention, the counting portion protrudes from the upper surface of the base body, and on an upper surface of the mounting portion is formed a conductor layer which is made of the one end of the wiring conductor and to which the light emitting element is electrically connected through a conductive adhesive, and a convexity made of an insulating material is formed around the conductor layer.

In this invention, the conductor layer is so configured that the conductor layer lies inwardly of an outer periphery of the light-emitting element.

In the invention, the convexity is so shaped that its side surfaces inclinedly extend outward gradually with increasing proximity to the base body.

The invention provides a light-emitting apparatus comprising:

a base body formed in a platy shape and made of ceramics;

a light-emitting element; and

a reflection member joined to all upper surface of the base body, which has, at a center of its upper principal surface, a convex mounting portion for mounting thereon the light-emitting element, and further has, at an outer periphery of its upper principal surface, a side wall portion formed so as to surround the mounting portion, an inner peripheral surface of which side wall portion is shaped into a reflection surface for reflecting light emitted from the light-emitting element,

wherein the base body is so designed that crystal grains contained in the ceramics range in average particle diameter from 1 to 5 μm.

In the invention, the light-emitting apparatus further comprises a light transmitting member disposed inside the side wall portion so as to cover the light-emitting element, which contains fluorescent materials for performing wavelength conversion on light emitted from the light-emitting element.

In the invention, the light-transmitting member is so disposed that an interval between its upper surface and the light-emitting section is kept in a range from 0.1 to 0.5 mm.

In the invention, the mounting portion is formed in a convex shape.

In the invention, the base body has a wiring conductor formed so as to extend from its upper surface to outer surface; the reflection member has, around the mounting portion, a through hole drilled all the way through from the upper principal surface to a lower principal surface thereof so as to lie below the optical path line; and an electrode of the light-emitting element and the wiring conductor formed on the upper surface of the base body are electrically connected to each other by means of a wire inserted through the through hole.

In the invention, the through hole is filled with an insulative paste containing insulative light-reflecting particles.

The invention provides an illumination apparatus constructed by setting up the light-emitting apparatus as set forth hereinabove in a predetermined arrangement.

According to the invention, the base body is so designed that crystal grains contained in the ceramic range in average particle diameter from 1 to 5 μm. Therefore, the density of the crystal grains is so high that the inter-grain boundary and interstices are extremely small, and the proportion of the crystal grains existing in the surface part of the base body is increased. In this construction, this makes it possible to effectively prevent the light emitted from the light-emitting element from finding its way into the base body, and thereby improve the reflectivity. As a result, the optical power of the light emitting apparatus can be enhanced.

Moreover, since a proper amount of asperities are created on the surface or the base body because of the high-density crystal grains existing in the surface part of the base body, it will be possible to cause moderate diffuse reflection of light emitted from the light-emitting element, and thereby increase the number of fluorescent materials subjected to light irradiation, As a result, the wavelength conversion efficiency can be increased; wherefore the optical power, brightness, and color rendering can be enhanced.

Further, since the base body is composed of high-density crystal grains, it follows that the thermal conductivity of the base body is enhanced, and thus heat emanating from the light-emitting element can be dissipated, through the base body, to the outside with high efficiency. This makes it possible to effectively prevent heat-induced degradation in the light emission efficiency of the light-emitting element; wherefore reduction of the optical power of the light-emitting apparatus can be avoided.

According to the invention, the light-emitting apparatus includes the package for housing the light-emitting element of the invention and the light-emitting element mounted on the mounting portion and electrically connected to the wiring conductor. Therefore, the light emitted from the light-emitting element can be reflected efficiently, and the number of the fluorescent materials subjected to excitation is increased; wherefore illumination characteristics such as optical power, brightness, and color rendering can be enhanced.

According to the invention, preferably, the interval between the upper surface of the light-transmitting member and the light-emitting section of the light-emitting element is kept in a range from 0.1 to 0.8 mm. Therefore, the light emitted from the light-emitting element can be wavelength-converted with high efficiency by the fluorescent materials contained in the light-transmitting member, and the wavelength-converted light is allowed to radiate out of the light-transmitting member effectively without suffering from disturbance caused by the fluorescent materials. Thus, excellent illumination characteristics such as brightness and color rendering can be achieved.

According to the invention, the one end of the wiring conductor is designed as the conductor layer to which the light-emitting element is electrically connected through the conductive adhesive. Around the conductor layer is formed a convexity made of an insulating material. Therefore, with the convexity, the conductive adhesive can be prevented from spreading outwardly of the conductor layer; wherefore the conductive adhesive has a uniform thickness. The light-emitting element can accordingly be mounted on the conductor layer horizontally. As a result, light is emitted from the light-emitting element at a desired exiting angle, and the emitted light is then reflected from the frame body at a desired radiation angle so as to radiate out properly, whereby making it possible to increase the radiation intensity of the light emitted from the light-emitting apparatus.

Moreover, since the light-emitting element can be mounted on the conductor layer horizontally, it follows that the heat emanating from the light-emitting element can be dissipated, through the conductive adhesive and the base body, to the outside with high efficiency. As a result, the temperature of the light-emitting element can be maintained with stability; wherefore the radiation intensity of the light emitted from the light-emitting element can be maintained high with stability.

Further, the light emitted from the light-emitting element can be effectively prevented from being applied to the conductive adhesive by the convexity. Hence, it never occurs that the light emitted from the light-emitting apparatus is absorbed by the conductive adhesive, and thus an undesirable decrease in the radiation intensity, brightness, and color rendering can be avoided effectively. There will thus be provided the light-emitting apparatus that offers high radiation intensity and excellent light emission characteristics.

According to the invention, the conductor layer is so configured that it lies inwardly of the outer periphery of the light-emitting element. Therefore, the conductive adhesive for joining together the conductor layer and the light-emitting element can be prevented from being exposed off the area between the conductor layer and the light-emitting element; wherefore the light emitted from the light-emitting element can be prevented from being applied to the conductive adhesive quite effectively. As a result, it never occurs that the light emitted from the light-emitting element is absorbed by the conductive adhesive or reflected therefrom as light exhibiting low radiation intensity. The radiation intensity of the light emitted from the light-emitting apparatus can accordingly be maintained high, and excellent brightness and color rendering can be attained.

Another advantage is that, even if the light emitted from the light-emitting element is ultraviolet light, the conductive adhesive will not suffer from quality degradation. Thus, the strength of bonding between the conductor layer and the light-emitting element can be kept sufficiently high; wherefore the steadfast fixation between the conductor layer and the light-emitting element can be maintained for a longer period of time. As a result, the electrical connection between the electrode of the light-emitting element and the conductor layer can be ensured for a longer period of time. The light-emitting apparatus can accordingly offer a longer service life.

According to the invention, the convexity is so shaped that its side surfaces inclinedly extend outward gradually with increasing proximity to the base body. Therefore, this makes air present at a corner portion formed between the side surfaces of the convexity and the upper surface of the base body easy to drain, and prevents the air from remaining at the corner portion. Accordingly, it is possible to effectively prevent that a void is formed in the conductive adhesive and the light transmitting member and peeling or a crack is caused by expansion of air in the void due to change in temperature or the like. In addition, it is possible to well reflect light on the outer inclined side surfaces of the convexity upward, and to improve the light emission efficiency.

According to the invention, the one end of the wiring conductor is designed as the conductor layer to which the light-emitting element is electrically connected through a conductive adhesive. The convexity is formed in the part of an upper surface of the conductor layer which part lies inwardly of the outer periphery of the light-emitting element. Therefore, with this convexity, the light-emitting element can be lifted to a higher level than the conductor layer, thereby creating a gap between the lower surface of the light-emitting element and the upper surface of the conductor layer without fail. Hence, it never occurs that the weight of the light-emitting element forces the conductive adhesive to flow outwardly of the conductor layer, and thus the conductive adhesive is applied onto the conductor layer in a uniform thickness. The light-emitting element can accordingly be mounted on the conductor layer horizontally. As a result, light is emitted from the light-emitting element at a desired exiting angle, and the emitted light is then reflected from the frame body at a desired radiation angle so as to radiate out properly, whereby making it possible to increase the radiation intensity of the light emitted from the light-emitting apparatus.

Moreover, since the conductive adhesive is applied onto the conductor layer in a uniform thickness, it will be possible to mount the light-emitting element on the conductor layer horizontally. Thus, the heat emanating from the light-emitting element can be dissipated, through the conductive adhesive and the base body, to the outside with high efficiency. As a result, the temperature of the light-emitting element can be maintained with stability; wherefore the radiation intensity of the light emitted from the light-emitting element can be maintained high with stability.

Further, being effectively prevented from flowing outwardly of the outer periphery of the light-emitting element, the conductive adhesive remains below the light-emitting element. This makes it possible to prevent the light emitted from the light-emitting element from being absorbed by the conductive adhesive flowing outwardly of the outer periphery of the light-emitting element. As a result, there will be provided the light-emitting apparatus that offers high radiation intensity and excellent optical characteristics such as brightness and color rendering.

According to the invention, since the mounting portion is so formed as to jut out, it follows that insulation is provided between the mounting portion and the lower end of the frame body without fail. This makes it possible to bring the lower end of the frame body close to the mounting portion, as viewed plane-wise, and thereby allow the light emitted from the light-emitting element to be reflected from the reflection surface of the frame body more satisfactorily.

According to the invention, the protruding mounting portion is so shaped that its side surfaces inclinedly extend outward gradually with increasing proximity to the base body. This makes it possible to enhance diffusivity of heat emanating from the light-emitting element, and to allow light to be efficiently reflected upward from the side surface of the protruding mounting portion. As a result, the light emission efficiency of the light-emitting element, as well as the wavelength conversion efficiency of the fluorescent materials, can be increased, and further, the light emitted from the light-emitting element or the fluorescent materials can be reflected upward efficiently. Hence, light output can be achieved with high radiation intensity for a longer period of time.

According to the invention, the light-emitting section of the light-emitting element is higher in level than the lower end of the reflection surface, and the light-transmitting member is so disposed that the interval between its upper surface and the light-emitting section is kept in a range from 0.1 to 0.5 mm. Thus, of the light beams emitted from the light-emitting element, the one that is allowed to radiate out directly from the upper opening of the frame body without being reflected from the reflection surface may have extremely high intensity. That is, the light emitted from the light-emitting element can be wavelength-converted with high efficiency by the fluorescent materials contained in the part of the light-transmitting member of predetermined thickness which is located above the light-emitting section of the light-emitting element, and then the wavelength-converted light is allowed to exit directly from the light-transmitting member without suffering from disturbance caused by the fluorescent materials. As a result, the light-emitting apparatus is capable of providing increased radiation intensity and excellent optical characteristics such as on-axis luminous intensity, brightness, and color rendering.

Even if heat emanating from the light-emitting element is transmitted to the base body, since the mounting portion is so formed as to jut out, it will be possible to secure as long a distance as possible between the mounting portion and the frame body, and to increase the contact area between the jutting part of the base body and the light-transmitting member, thereby improving the heat-dissipation property. Thus, transmission of heat to the frame body can be prevented effectively. As a result, the frame body can be effectively protected from deformation due to the difference in thermal expansion between the frame body and the base body.

According to the invention, preferably, the light-transmitting member is so designed that its center portion is larger in arithmetic average surface roughness than its outer peripheral portion. This helps reduce the difference in radiation intensity between the light exiting from the center portion and the light exiting from the outer peripheral portion in the light-transmitting member. Specifically, the light that has been emitted from the light-emitting element and then radiated directly from the center portion of the surface of the light-transmitting member without being reflected from the frame body or the like has high intensity. This light is appropriately scattered by a rough surface in the center portion of the surface of the light-transmitting member so that its intensity may be slightly decreased. In this way, the intensity of the light which is emitted from the center portion of the surface of the light-transmitting member can be approximated to low intensity of the light that has been radiated from the outer peripheral portion of the surface of the light-transmitting member after being reflected from the reflection member; wherefore the difference in radiation intensity between the center portion and the outer peripheral portion in the light-transmitting member can be reduced. As a result, the light-emitting apparatus is capable of emitting uniform light in a wider area. Moreover, it is possible to avoid glare, i.e. a phenomenon which stings human eyes, resulting from concentration of radiation intensity in certain part of the light-emitting surface. Thus, detrimental effects on human eyes can be minimized.

According to the invention, the mounting portion protrudes from the upper surface of the base body, and on an upper surface of the mounting portion is formed a conductor layer which is made of the one end of the wiring conductor and to which the light-emitting element is electrically connected through a conductive adhesive, and a convexity made of an insulating material is formed around the conductor layer. Therefore, the light having been emitted laterally or obliquely downwardly from the side of the light-emitting element can be reflected from the reflection surface of the frame body satisfactorily. Thus, the light can be reflected from the frame body at a desired radiation angle so as to radiate out satisfactorily, without being absorbed by the joint portion between the frame body and the base body or the surface of the base body. As a result, the radiation intensity of the light emitted from the light-emitting apparatus can be maintained high with stability.

Since the mounting portion is so formed as to jut out, it follows that insulation is provided between the mounting portion and the lower end of the reflection member without fail. This makes it possible to bring the lower end of the frame body close to the mounting portion, as viewed plane-wise, and thereby allow the light emitted from the light-emitting element to be reflected from the reflection surface of the frame body more satisfactorily.

Moreover, with the convexity made of an insulating material, the conductive adhesive can be prevented from spreading outwardly of the conductor layer; wherefore the conductive adhesive has a uniform thickness. The light-emitting element can accordingly be mounted on the conductor layer horizontally. As a result, light is emitted from the light-emitting element at a desired exiting angle, and the emitted light is then reflected from the frame body at a desired radiation angle so as to radiate out properly, whereby making it possible to increase the radiation intensity of the light emitted from the light-emitting apparatus.

Moreover, since the light-emitting element can be mounted on the conductor layer horizontally, it follows that the heat emanating from the light emitting element can be dissipated, through the conductive adhesive and the base body, to the outside with high efficiency. As a result, the temperature of the light-emitting element can be maintained with stability wherefore the radiation intensity of the light emitted from the light-emitting element can be maintained high with stability.

Further, the light emitted from the light-emitting element can be effectively prevented from being applied to the conductive adhesive by the convexity. Hence, it never occurs that the light emitted from the light-emitting apparatus is absorbed by the conductive adhesive, and thus an undesirable decrease in the radiation intensity, brightness, and color rendering can be avoided effectively. There will thus be provided the light-emitting apparatus that offers high radiation intensity and excellent light emission characteristics.

According to the invention, the conductor layer lies inwardly of the outer periphery of the light-emitting element. In this way, the conductive adhesive for joining together the conductor layer and the light-emitting element can be prevented from being exposed off the area between the conductor layer and the light-emitting element; wherefore the light emitted from the light-emitting element can be prevented from being applied to the conductive adhesive quite effectively. As a result, it never occurs that the light emitted from the light-emitting element is absorbed by the conductive adhesive or reflected therefrom as light exhibiting low radiation intensity. The radiation intensity of the light emitted from the light-emitting apparatus can accordingly be maintained high, and excellent brightness and color rendering can be attained.

Another advantage is that, even if the light emitted from the light-emitting element is ultraviolet light, the conductive adhesive will not suffer from quality degradation. Thus, the strength of bonding between the conductor layer and the light-emitting element can be kept sufficiently high; wherefore the steadfast fixation between the conductor layer and the light-emitting element can be maintained for a longer period of time. As a result, the electrical connection between the electrode of the light-emitting element and the conductor layer can be ensured for a longer period of time. The light-emitting apparatus can accordingly offer a longer service life.

According to the invention, the convexity is so shaped that its side surfaces inclinedly extend outward gradually with increasing proximity to the base body. Therefore, this makes air present at a corner portion formed between the side surfaces of the convexity and the upper surface of the mounting portion easy to drain, and prevents the air from remaining at the corner portion. Accordingly, it is possible to effectively prevent that a void is formed in the conductive adhesive and the light-transmitting member and peeling or a crack is caused by expansion of air in the void due to change in temperature or the like. In addition, it is possible to well reflect light on the outer inclined side surfaces of the convexity upward, and to improve the light emission efficiency.

According to the invention, the light-emitting apparatus includes the base body formed in a platy shape and made of ceramics; the light-emitting element; the reflection member joined to the upper surface of the base body, which has, at the center of its upper principal surface, the mounting portion for mounting thereon the light emitting element, and further has, at the outer periphery of its upper principal surface, the side wall portion formed so as to surround the mounting portion, the inner peripheral surface of which side wall portion is shaped into the reflection surface for reflecting light emitted from the light-emitting element; and the light transmitting member disposed inside the side wall portion so as to cover the light-emitting element, which contains fluorescent materials for performing wavelength conversion on light emitted from the light-emitting element. The light-transmitting member is so disposed that an interval between its upper surface and the light emitting section is kept in a range from 0.1 to 0.5 mm, and the base body. Thus, of the light beams emitted from the light-emitting element, the one that is allowed to radiate upward directly from the light-emitting element without being reflected from the reflection surface may have extremely high intensity. That is, the light emitted from the light-emitting element can be wavelength-converted with high efficiency by the fluorescent materials contained in that part of the light-transmitting member of predetermined thickness which is located above the light-emitting section of the light-emitting element, and then the wavelength converted light is allowed to exit directly from the light-transmitting member without suffering from disturbance caused by the fluorescent materials. As a result, the light-emitting apparatus is capable of providing increased radiation intensity and excellent optical characteristics such as on-axis luminous intensity, brightness, and color rendering.

Moreover, heat emanating from the light-emitting element is easily transmitted from the mounting portion to the side wall portion that are formed in one piece. In particular, when the reflection member is made of a metal, heat can be transmitted to the side wall portion more swiftly, and then dissipated from the outer side of the side wall portion to the outside satisfactorily. Thus, the reflection member can be effectively protected from deformation due to the difference in thermal expansion between the reflection member and the base body; wherefore the desired radiation light characteristics can be maintained for a longer period of time.

Further, the reflection surface has its lower end located on or below the optical path line connecting the light-emitting section lying at the end of the light-emitting element and the corner between the upper surface and the side surface of the mounting portion. This allows direct light emitted laterally or downwardly from the light-emitting element to be efficiently reflected from the reflection surface, thereby attaining extremely high radiation light intensity.

According to the invention, the base body has a wiring conductor formed so as to extend from its upper surface to outer surface. The reflection member has, around the mounting portion, a through hole drilled all the way through from the upper principal surface to the lower principal surface thereof so as to lie below the optical path line. The electrode of the light-emitting element and the wiring conductor formed on the upper surface of the base body are electrically connected to each other by means of a wire inserted through the through hole. In this construction, direct light emitted from the light-emitting element is reflected from the reflection surface above the through hole drilled in the reflection member for inserting thereinto the wire. Thus, the direct light can be effectively prevented from being directed into and absorbed in the through hole, thereby increasing the radiation light intensity.

Moreover, the light-emitting element is, at its entire lower surface, joined to the mounting portion of the reflection member. This make it possible to transmit the heat emanating from the light-emitting element to the reflection member satisfactorily and thereby improve the heat-dissipation property.

Furthermore, it is possible to effectively suppress that light leaks through the through hole for inserting the wire therethrough which through hole is formed in the reflection member and is absorbed into the base body, by setting the average particle diameter of the crystal grains contained in ceramics to a range of 1 to 5 μm to improve the reflectivity of the base body.

According to the invention, the through hole is filled with an insulative paste containing insulative light-reflecting particles. In this way, even though the light emitted from the light-emitting element or the fluorescent materials is directed into the through hole, the light can be effectively reflected upward from the light-reflecting particles. Hence, the light-emitting apparatus is capable of offering satisfactory optical characteristics such as high radiation intensity, on-axis luminous intensity, brightness, and color rendering.

According to the invention, the illumination apparatus of the invention is constructed by setting up the light-emitting apparatus of the invention in a predetermined arrangement. In this construction, light emission is effected by exploiting recombination of electrons in the light-emitting element formed of a semiconductor. Thus, there is provided a compact illumination apparatus that has the advantage, in terms of power saving and long lifetime, over a conventional illumination apparatus for affecting light emission through electrical discharge. As a result, variation in the center wavelength of the light emitted from the light emitting element can be suppressed; wherefore the illumination apparatus will succeed in irradiating light with stable radiation light intensity and angle (luminous intensity distribution) for a longer period of time, and in avoiding color unevenness and unbalanced illumination distribution on a to-be-irradiated surface.

Moreover, by setting up the light-emitting apparatus of the invention as a light source in a predetermined arrangement, followed by arranging around the light-emitting apparatus an optical component optically designed in a given configuration such as a reflection jig, an optical lens, or a light diffusion plate, it is possible to realize an illumination apparatus capable of emitting light with given luminous intensity distribution.

### BRIEF DESCRIPTION OF THE DRAWINGS

Other and further objects, features, and advantages of the invention will be more explicit from the following detailed description taken with reference to the drawings wherein:

FIG. 1 is a sectional view showing a light-emitting apparatus according to the first embodiment of the invention;

FIG. 2 is a sectional view showing a light-emitting apparatus according to a second first embodiment of the invention;

FIG. 3A is an enlarged plan view showing one example of a conductor layer and a convexity disposed in the light-emitting apparatus of the invention, and FIG. 3B is an enlarged plan view showing another example of a conductor layer and a convexity disposed in the light-emitting apparatus of the invention;

FIG. 4 is a sectional view showing a light-emitting apparatus according to a third embodiment of the invention;

FIG. 5 is a sectional view showing a light-emitting apparatus according to a fourth embodiment of the invention;

FIG. 6 is a sectional view showing a light-emitting apparatus according to a fifth embodiment of the invention;

FIG. 7 is a sectional view showing a light-emitting apparatus according to a sixth embodiment of the invention;

FIG. 8 is a sectional view for explaining about an interval between an upper surface of the light-transmitting member and an active layer disposed in the light emitting apparatus of the invention;

FIG. 9 is a sectional view for explaining about an interval between an upper surface of a light-transmitting member and an active layer disposed in the light emitting apparatus of the invention;

FIG. 10 is a sectional view showing a light-emitting apparatus according to a seventh embodiment of the invention;

FIG. 11 is a sectional view showing a light-emitting apparatus according to an eighth embodiment of the invention;

FIG. 12A is an enlarged plan view showing one example of a conductor layer and a convexity disposed in the light-emitting apparatus of the invention, and FIG. 12B is an enlarged plan view showing another example or a conductor layer and a convexity disposed in the light-emitting apparatus of the invention;

FIG. 13A is an enlarged plan view showing one example of a conductor layer and a convexity disposed in the light-emitting apparatus of the invention, and FIG. 13B is an enlarged plan view showing another example of a conductor layer and a convexity disposed in the light-emitting apparatus of the invention;

FIG. 14 is a sectional view showing a light-emitting apparatus according to a ninth embodiment of the invention;

FIG. 15A is an enlarged perspective view showing one example of a conductor layer and a convexity disposed in the light-emitting apparatus of the invention, and FIG. 15B is an enlarged perspective view showing another example of a conductor layer and a convexity disposed in the light-emitting apparatus of the invention;

FIG. 16A is an enlarged plan view showing one example of a conductor layer and a convexity disposed in the light-emitting apparatus according to the invention, and FIG. 16B is an enlarged plan view showing another example of a conductor layer and a convexity disposed in the light-emitting apparatus according to the invention;

FIG. 17 is a sectional view showing a light-emitting apparatus according to a tenth embodiment of the invention;

FIG. 18 is a sectional view showing a light-emitting apparatus according to an eleventh embodiment of the invention;

FIG. 19 is a sectional view showing a light-emitting apparatus according to a twelfth embodiment of the invention;

FIG. 20 is a sectional view showing a light-emitting apparatus according to a thirteenth embodiment of the invention;

FIG. 21 is a sectional view for explaining about an interval between an upper surface of a light-transmitting member and an active layer disposed in the light-emitting apparatus of the invention;

FIG. 22 is a sectional view for explaining about an interval between an upper surface of a light-transmitting member and an active layer disposed in the light-emitting apparatus of the invention;

FIG. 23 is a plan view showing an illumination apparatus according to a fourteenth embodiment of the invention;

FIG. 24 is a sectional view of an illumination apparatus shown in FIG. 23;

FIG. 25 is a plan view showing an illumination apparatus according to a fifteenth embodiment of the invention;

FIG. 26 is a sectional view of an illumination apparatus shown in FIG. 25;

FIG. 27 is a view showing a result of intensity measurement of the light-emitting apparatus according to the first embodiment of the invention;

FIG. 28 is a graph showing a relationship between light emission intensity and an interval from the upper surface of a light-transmitting member to an active layer disposed in the light-emitting apparatus according to the sixth embodiment of the invention;

FIG. 29 is a sectional view showing a variety of optical path line patterns as seen in the light-emitting apparatus shown in FIG. 19;

FIG. 30 is a graph showing the relationship among a mounting portion's length L, an interval X between a light-transmitting member's upper surface and an active layer, and on-axis luminous intensity, as seen in the light-emitting apparatus of the invention;

FIG. 31 is a sectional view of a light-emitting apparatus according to the first related art;

FIG. 32 is a sectional view of a package for housing a light-emitting element according to the second related art; and

FIG. 33 is a sectional view of a light-emitting apparatus according to the third related art.

### DETAILED DESCRIPTION

Now referring to the drawings, preferred embodiments of the invention are described below.

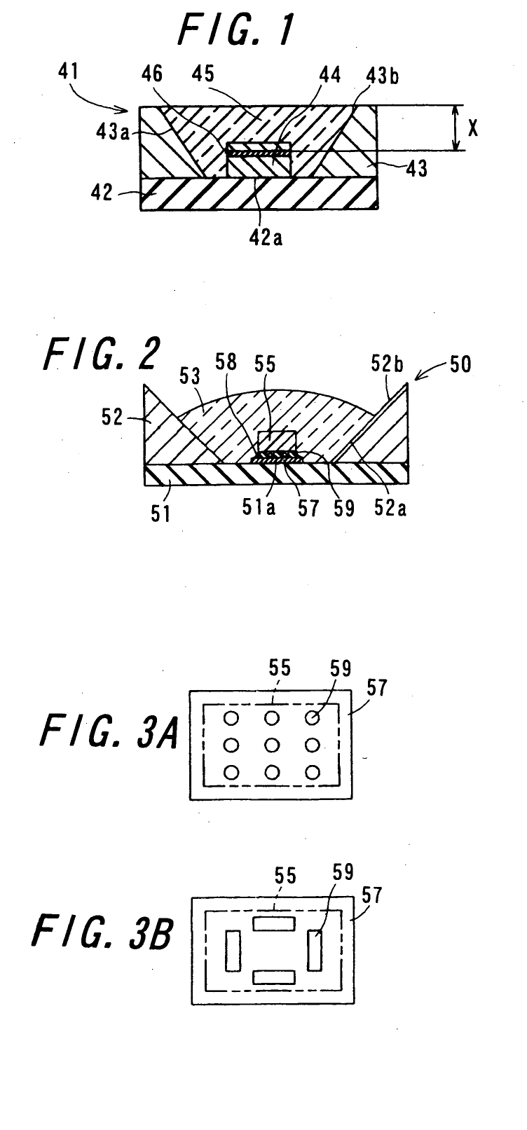

Now, a detailed description will be given below as to a package for housing a light-emitting element (hereafter, referred also to simply as “package”) and a light-emitting apparatus according to the invention. FIG. 1 is a sectional view showing a light-emitting apparatus 41 according to a first embodiment of the invention. The light-emitting apparatus 41 is mainly constituted of a base body 42; a frame body 43; a light-emitting element 44; and a light-transmitting member 45 which contains fluorescent materials (not shown). Thus, the light-emitting apparatus 41 can output light emitted from the light-emitting element 4 to the outside.

The package embodying the invention includes the base body 42; the frame body 43; a wiring conductor (not shown); and the light-transmitting member 45. The base body 42 is made of ceramics and has, on its upper surface, a mounting portion 42a for mounting thereon the light-emitting element 44. The frame body 43 is joined to the outer periphery of the upper surface of the base body 42 so as to surround the mounting portion 42a. Moreover, the frame body 43 has its inner peripheral surface shaped into a reflection surface 43a for reflecting light omitted from the light-emitting element 44. The wiring conductor has its one end formed on the upper surface of the base body 42 so as to be electrically connected to the electrode of the light-emitting element 44, and has the other end led out to a side surface or a lower surface of the base body 42. The light-transmitting member 45 is disposed inside the frame body 43 so as to cover the light-emitting element 44, and contains fluorescent material for performing wavelength conversion on the light emitted from the light-emitting element 44.

The base body 42 is made of a ceramic insulating material such as aluminum oxide sintered body, aluminum nitride sintered body, mullite sintered body, or glass ceramics. The base body 42 has, on its upper surface, the mounting portion 42a for mounting thereon the light-emitting element 44, so that it may function as a supporting member for supporting the light-emitting element 44.

Moreover, in the base body 42, ceramic crystal grains range in average particle diameter from 1 to 5 μm. That is, the density of crystal grains is so high that the proportion of the crystal grains existing in the surface part of the base body 42 is increased. Thus, light which finds its way from between the crystal grains into the base body 42 can effectively be cut out, and the reflectivity of the upper surface of the base body 42 is accordingly improved; wherefore the optical power of the light-emitting apparatus 41 can be enhanced.

Further, the arithmetic average roughness of the upper surface of the base body 42 is of such appropriate degree as to allow the light emitted from the light-emitting element 44 to be reflected from the upper surface of the base body 42 in every direction. As a result, the number of the fluorescent materials that give forth light after being excited by the light reflected from the inner peripheral surface of the frame body 43 is increased; wherefore the optical power, brightness, and color rendering of the light-emitting apparatus 41 can be enhanced.

If the average particle diameter of the ceramic crystal grains is larger than 5 μm, the proportion of the crystal grains existing in the surface part of the base body 42 is decreased. Thus, light which finds its way from between the crystal grains into the base body 42 is increased, and accordingly the reflectivity of the upper surface of the base body 42 tends to decrease. As a result, since the light emitted from the light-emitting element 44 or the fluorescent materials cannot be reflected from the upper surface of the base body 42 with high efficiency, it follows that the optical power of the light-emitting apparatus 41 tends to decrease. By contrast, if the average particle diameter of the ceramic crystal grains in smaller than 1 μm, the arithmetic average roughness of the upper surface of the base body 42 is decreased, and thus the light emitted from the light-emitting element 44 is prone to being specularly reflected from the upper surface of the base body 42. This makes it difficult to achieve omnidirectional reflection. As a result, since the fluorescent materials other than the specular reflection direction-wise fluorescent materials cannot be excited readily, it follows that mainly the specular reflection direction-wise fluorescent materials are responsible for wavelength conversion, which leads to poor wavelength conversion efficiency. This may cause reduction of the optical power of the light-emitting apparatus 41.

Moreover, the base body 42 is so designed that the ceramic crystal grains range in average particle diameter from 1 μm to 5 μm. Thus, in the base body 42, the density of the crystal grains exhibiting high thermal conductivity is so high that the thermal conductivity of the base body 42 is enhanced. This makes it possible to allow the heat emanating from the light-emitting element 44 to be dissipated, through the base body 42, to the outside with high efficiency, Hence, heat-induced degradation in the light emission efficiency of the light emitting element 44 can be prevented successfully; wherefore reduction of the optical power of the light-emitting apparatus 41 can be avoided effectively.

Formed on the mounting portion 42a is the wiring conductor (not shown) to which the light-emitting element 44 is electrically connected. The wiring conductor is led out, through a wiring layer (not shown) formed within the base body 42, to the outer surface of the light-emitting apparatus 41, so as to be connected to an external electric circuit board through a lead made of a brazing filler or metal material, thereby establishing electrical connection between the light-emitting element 44 and the external electric circuit.

The examples of means for connecting the light-emitting element 44 to the wiring conductor include a wire-bonding method and a flip-chip bonding method. According to the former, connection is established by using a wire such as an Au line or Al line. According to the latter, connection is established by connecting an electrode formed on the lower surface of the light-emitting element 44 to the wiring conductor through such connecting means as a solder bump made of Au-tin (Sn) solder, Sn—Ag solder, Sn—Ag—Cu solder, of Sn-lead (Pb), or a metal bump made of a metal such as Au or Ag. The flip-chip bonding method is more desirable for connection. By adopting such methods, the wiring conductor can be disposed immediately below the light-emitting element 44 on the upper surface of the base body 42. This eliminates the need to secure an extra area for the wiring conductor around the light-emitting element 44 on the upper surface of the base body 42. Hence, it never occurs that the light emitted from the light-emitting element 44 is absorbed in this wiring conductor area of the base body 42. Reduction of the radiation optical power can accordingly be avoided effectively.

The wiring conductor, which is formed of a metallized layer made of powder of a metal such as W, Mo, Mn, Cu, or Ag, is disposed on the surface of or inside the base body 42. The wiring conductor may also be formed by burying a lead terminal made of a metal such as an Fe—Ni—Co alloy in the base body 42. In another alternative, the wiring conductor may be formed by fitting an input/output terminal formed of an insulator carrying a wiring conductor into a through hole drilled in the base body 42.

Moreover, it is preferable that the wiring conductor has its exposed surface coated with a highly corrosion-resistant metal such as Ni or Au in the thickness ranging from 1 to 20 μm. This makes it possible to protect the wiring conductor against oxidative corrosion effectively, and to strengthen the connection between the light-emitting element 44 and the wiring conductor. Accordingly, the exposed surface of the wiring conductor should preferably be coated with for example a 1 to 10 μm-thick Ni plating layer and a 0.1 to 3 μm-thick Au plating layer successively by the electrolytic plating method or electroless plating method.

Onto the upper surface of the base body 42 is attached the frame body 43 with use of a bonding material such as solder, a brazing filler material such as Ag brazing filler, or an epoxy-resin adhesive. The frame body 43 has a through hole 43a formed such that its upper opening is larger than its lower opening and, on its inner peripheral surface, a reflection surface 43b capable of reflecting the light emitted from the light-emitting element 44 at a high reflectivity. The inner peripheral surface having such a reflection surface is obtained as follows. For example, firstly, the frame body 43 is formed of a high-reflectivity metal such as Al, Ag, Au, platinum (Pt), titanium (Ti), chromium (Cr), or Cu through a cutting process, die-molding process, or the like method. Then, the inner peripheral surface thereof is flattened into a reflection surface through a polishing process such as electrolytic polishing or chemical polishing. In the alternative, firstly, the frame body 43 is formed of a Cu—W alloy or SUS (stainless steel) alloy that exhibits excellent weatherability and moisture-resistance. Then, on the inner peripheral surface thereof is formed a metal thin film such as Al, Ag, or Au by means of metal plating or vapor deposition. In a case where the inner peripheral surface is made of a metal, such as Ag or Cu, that is susceptible to discoloration resulting from oxidation, it is preferable to laminate on its surface low-melting-point glass, sol-gel glass, silicone resin, or epoxy resin that exhibits excellent transmittance in regions ranging from ultraviolet light to visible light. This makes it possible to improve the corrosion resistance and chemical resistance or weather resistance of the inner peripheral surface of the frame body 43.

Moreover, an arithmetic average roughness Ra at the top of the inner peripheral surface of the frame body 43 is preferably set at 0.1 μm or less. This makes it possible to allow the light emitted from the light-emitting element 44 to be satisfactorily reflected therefrom in the direction of the upper part of the light-emitting apparatus. If Ra exceeds 0.1 μm, the light emitted from the light-emitting element 44 cannot be satisfactorily reflected from the inner peripheral surface of the frame body 43 in the direction of the upper part of the light-emitting apparatus, and in addition diffuse reflection tends to occur within the light-emitting apparatus 41. As a result, loss of light within the light-emitting apparatus 41 may become significant, which results in difficulty in allowing light to radiate out at a desired radiation angle satisfactorily.

In the invention, the light-transmitting member 45 is preferably made of a material that is not much different in refractive index from the light-emitting element 44 and exhibits excellent transmittance in regions ranging from ultraviolet light to visible light. For example, the light-transmitting member 45 is preferably made of light-transmitting resin such as silicone resin, epoxy resin, or urea resin, or low-melting-point glass or sol-gel glass. In this way, occurrence of light reflection loss resulting from the difference in refractive index between the light-transmitting member 45 and the light-emitting element 44 can be avoided effectively. The light emitting apparatus 41 will thus succeed in allowing light to radiate out highly efficiently with desired radiation-intensity and radiation-angle distribution. The light-transmitting member 45 such as shown herein is formed by charging the material inside the frame body 43 so as to cover the light-emitting element 44 by an injector such as a dispenser, followed by performing heat-hardening thereon in an oven.

Moreover, the light-transmitting member 45 has a predetermined content of inorganic or organic fluorescent materials that give forth light of different colors such as blue, red, green, and yellow individually through recombination of electrons existing therein after being excited by the light emitted from the light-emitting element 44. This makes it possible to output light having desired emission spectrum and color.

Further, the light-transmitting member 45 is preferably so disposed that an interval between its upper surface and the light-emitting section 46 of the light-emitting element 44 ranges from 0.1 to 0.8 mm. In this way, the light emitted from the light-emitting element 44 can be wavelength-converted with high efficiency by the fluorescent materials contained in that part or the light-transmitting member 45 of predetermined thickness which is located above the light-emitting section 46 of the light-emitting element 44. In addition, the wavelength-converted light can be effectively protected from disturbance caused by the fluorescent materials, so that it may radiate out from the light-transmitting member 45 with efficiency. As a result, the light emitting apparatus 41 is capable of providing improved optical power and excellent illumination characteristics such as brightness and color rendering.

If the interval X between the light-emitting section 46 of the light-emitting element 44 and the upper surface of the light-transmitting member 45 (refer to FIG. 1) is longer than 0.8 mm, although, of the fluorescent materials, the ones existing closer to the light emitting element 44 are capable of performing wavelength conversion satisfactorily on the light emitted from the light-emitting element 44, it is difficult to allow the wavelength-converted light to exit from the light-transmitting member 45 with efficiency. That is, since the travel of the wavelength-converted light is disturbed by the fluorescent materials existing near the upper surface of the light-transmitting member 45, it follows that radiation of light to the outside cannot be achieved successfully.

By contrast, if the interval X between the light-emitting section 46 of the light-emitting element 44 and the upper surface of the light-transmitting member 45 is shorter than 0.1 mm, the number of the fluorescent materials that are excited through radiation of light emitted from the light-emitting element 44 is reduced. This makes efficient wavelength conversion difficult. In this case, there is an undesirable increase in the quantity of low-luminosity light of certain wavelength that is transmitted through the light-transmitting member 45 without undergoing wavelength conversion, with the result that satisfactory optical power and excellent illumination characteristics such as brightness and color rendering cannot be achieved.

Moreover, the light-emitting element 44 may be formed of any given element so long as it gives forth light exhibiting an emission energy spectrum having a peak wavelength in ultraviolet to infrared regions. From the standpoint of emitting white light or light of various colors with high visibility, it is preferable to use an element that gives forth near-ultraviolet to blue-color light at a wavelength in a range from 300 to 500 nm. For example, there is known an element formed by stacking on a sapphire substrate a buffer layer, an n-type layer, a light-emitting layer, and a p-type layer one by one, the light-emitting layer of which is of a gallium nitride-based compound semiconductor such as GaN, GaAlN, InGaN, or InGaAlN, or of silicon carbide-based compound semiconductor or ZnSe (zinc selenide).

FIG. 2 is a sectional view showing the light-emitting apparatus 50 according to a second embodiment of the invention. The light-emitting apparatus 50 is mainly constituted of a base body 51; a reflection member 52 serving as a frame body; a light-transmitting member 53; a conductor layer 57 and convexity 59.

A package for housing a light-emitting element embodying the invention includes the base body 51, the frame-like reflection member 52; and the conductor layer 57. The base body 51 has, at the center of its upper surface, a mounting portion 51a for mounting thereon a light-emitting element 55. The reflection member 52 is disposed at the outer periphery of the upper surface of the base body 51 so as to surround the mounting portion 51a. The conductor layer 57 is formed on the mounting portion 51a, to which conductor layer the light-emitting element 55 is electrically connected through a conductive adhesive 8. Moreover, the convexity 59 is formed in a part of an upper surface of the conductor layer 57 which part lies inwardly of the outer periphery of the light emitting element 55. Note that, a wiring conductor is provided in the package. The wiring conductor has one end formed on the upper surface of the base body 51 and electrically connected to an electrode of the light-emitting element 55, and another end led out to a side surface or lower surface of the base body 51. The one end of the wiring conductor is designed as the conductor layer 57.

In the invention, the base body 51 is made of ceramics such as alumina ceramics, aluminum nitride sintered body, mullite sintered body, or glass ceramics, or a resin material such as epoxy resin. The base body 51 has, on its upper surface, the mounting portion 51a for mounting thereon the light-emitting element 55. In a case where the base body 51 is made of ceramics, like the first embodiment of the invention, it is preferable that the ceramic crystal grains range in average particle diameter from 1 μm to 5 μm

Formed on the mounting portion 51a is the conductor layer 57 to which the light-emitting element 55 is electrically connected, for fixedly mounting the light-emitting element 55 on the base body 51. The conductor layer 57 is led out, through a wiring layer (not shown) formed within the base body 51, to the outer surface of the light-emitting apparatus. Upon this part led out to the outer surface of the light-emitting apparatus being connected to an external electric circuit board, electrical connection is established between the light-emitting element 55 and the external electric circuit.

In a case where the base body 51 is made of ceramics, on the upper surface thereof is formed the conductor layer 57 by firing a metal paste of W, Mo—Mn, Cu, or Ag at a high temperature. On the other hand, in a case where the base body 51 is made of a resin material, a molded lead terminal made of Cu or Fe—Ni alloy is fixedly arranged within the base body 51. The conductor layer 57 is formed in that way.

The convexity 59 is formed in the part of the upper surface of the conductor layer 57 which part lies inwardly of the outer periphery of the light-emitting element 55. The convexity 59 may be made of either a conductive material or an insulating material. In a case where the convexity 59 is made of insulative ceramics, for example, the convexity 59 is formed by print-coating a ceramic paste predominantly composed of a material used for forming the base body 51, followed by firing the ceramic paste at a high temperature together with the metal paste to be formed into the conductor layer 57. Moreover, in a case where the base body 51 is made of a resin material, for example, the convexity 59 is formed by means of die-molding, using the same material as that used for the base body 51, concurrently with the formation of the base body 51.

In the case of employing a conductive material, the convexity 59 is formed by print-coating a metal paste onto the upper surface of the conductor layer 57, followed by firing, or formed by creating a projection in the lead terminal through a cutting process or the like method.

As described above, the conductor layer 57 has the convexity 59 formed in the part of its upper surface which lies inwardly of the outer periphery of the light emitting element 55. With the convexity 59, the light-emitting element 55 can be lifted to a higher level than the conductor layer 57, thereby creating a gap between the lower surface of the light emitting element 55 and the upper surface of the conductor layer 57 without fail. Thus, it never occurs that the weight of the light-emitting element 55 forces a conductive adhesive 58 to flow outwardly of the conductor layer 57, and thus the conductive adhesive 58 has a uniform thickness. The light-emitting element 55 can accordingly be mounted on the conductor layer 57 horizontally. As a result, light is emitted from the light-emitting element 55 at a desired exiting angle, and the emitted light is then reflected from the reflection member 52 at a desired radiation angle so as to radiate out properly, whereby making it possible to increase the radiation intensity of the light emitted from the light-emitting apparatus.

Moreover, since the conductive adhesive 58 is applied onto the conductor layer 57 in a uniform thickness, it will be possible to mount the light-emitting element 55 on the conductor layer 57 horizontally. Thus, the heat emanating from the light-emitting element 55 can be dissipated, through the conductive adhesive 58 and the base body 1, to the outside with high efficiency. As a result, the temperature of the light-emitting element 55 can be maintained with stability; wherefore the radiation intensity of the light emitted from the light-emitting element 55 can be maintained high with stability.

Further, being effectively prevented from flowing outwardly of the outer periphery of the light-emitting element 55, the conductive adhesive 58 remains below the light-emitting element 55. This makes it possible to prevent the light emitted from the light-emitting element 55 from being absorbed by the conductive adhesive 58 flowing outwardly of the outer periphery of the light-emitting element 55. As a result, there will be provided the light-emitting apparatus 50 that offers high radiation intensity and excellent optical characteristics such as brightness and color rendering.

It is preferable that the convexity 59 ranges in height from 0.01 mm to 0.1 mm. In this way, a good meniscus of the conductive adhesive 58 can be created between the light-emitting element 55 and the conductor layer 57, whereby making it possible to prevent the flowing of the conductive adhesive 58 more effectively and thereby increase the bonding strength between the light-emitting element 55 and the conductor layer 57.

FIGS. 3A and 3B show enlarged plan views of the conductor layer 57 and the convexity 59. As shown in FIG. 3A, for example, a plurality of hemispherical convexities 59 are formed in that part of the upper surface of the conductor layer 57 which lies inwardly of the outer periphery of the light-emitting element 55. In the alternative, as shown in FIG. 3B, a plurality of rectangular convexities 59 are formed in that part of the upper surface of the conductor layer 57 which lies inwardly of the outer periphery of the light emitting element 55, so as to be parallel to the outer edges of the light-emitting element 55. As shown in FIGS. 3A and 3B, by providing a plurality of convexities 59, it is possible to create a gap between the lower surface of the light-emitting element 55 and the upper surface of the conductor layer 57 without fail, and thereby create a good meniscus of the conductive adhesive 8 between the upper surface of the conductor layer 57 and the lower surface of the light-emitting element 55. Here, it is important for the convexities 59 to be arranged in a well-balanced manner so that the light-emitting element 55 may stay horizontal to the conductor layer 57. By forming on the conductor layer 57 the convexity 59 that is smaller area than that of the lower surface of the light-emitting element 55, even if the lower surface of the light-emitting element 55 is joined to the conductor layer 57 through the conductive adhesive 58, it is possible to prevent the conductive adhesive 58 for joining together the conductor layer 57 and the light-emitting element 55 from spreading outwardly of the conductor layer 57. Since the conductive adhesive 58 is applied uniformly onto the mounting portion 51a, it follows that the light-emitting element 55 is mounted on the mounting portion 51a horizontally.

Connection of the light-emitting element 55 is made, at the electrode formed on the lower surface thereof, through the conductive adhesive 58 such as an Ag paste or gold (Au)-tin (Sn) solder.

It is preferable that the conductor layer 57 has its exposed surface coated with a highly corrosion-resistant metal such as Ni or Au in the thickness ranging from 1 to 20 μm. This makes it possible to protect the conductor layer 57 against oxidative corrosion effectively, and to strengthen the connection between the light-emitting element 55 and the conductor layer 57. Accordingly, the exposed surface of the conductor layer 57 should preferably be coated with for example a 1 to 10 μm-thick Ni plating layer and a 0.1 to 3 μm-thick Au plating layer successively by the electrolytic plating method or electroless plating method.

Moreover, onto the upper surface of the base body 51 is attached the reflection member 52 with use of a bonding material such as solder, a brazing filler material such as Ag brazing filler, or an epoxy-resin adhesive. The reflection member 52 has a through hole 2a drilled at the center thereof. Preferably, the inner peripheral surface of the through hole 2a is shaped into a reflection surface 2b for reflecting light emitted from the light-emitting element 55 and the fluorescent materials.

The reflection surface 2b is formed by performing cutting, die-molding, or polishing on the reflection member 52 to obtain a smooth surface exhibiting high light reflection efficiency, or formed by coating the inner peripheral surface of the through hole 2a with a metal thin film of a high reflectivity metal such as Al, Ag, Au, platinum (Pt), titanium (Ti), chromium (Cr), or Cu by means of plating or vapor deposition. In a case where the reflection surface 2b is made of a metal, such as Ag or Cu, that is susceptible to discoloration resulting from oxidation, it is preferable to laminate on its surface for example a 1 to 10 μm-thick Ni plating layer and a 0.1 to 3 μm-thick Au plating layer successively by the electrolytic plating method or electroless plating method. This makes it possible to improve the corrosion resistance of the reflection surface 2b.

Moreover, an arithmetic average roughness Ra at the top of the reflection surface 2b is preferably adjusted to fall in a range of 0.004 to 4 μm. This makes it possible to allow the light emitted from light-emitting element 55 and the fluorescent materials to be satisfactorily reflected from the reflection surface 2b. If Ra exceeds 4 μm, the light emitted from the light-emitting element 55 cannot be reflected evenly with case, and diffuse reflection tends to occur within the light-emitting apparatus. By contract, if Ra is less than 0.004 μm, it will be difficult to obtain such a reflection surface as offering the above-described effect with stability and high efficiency.

For example, in the reflection surface 2b, its vertical sectional profile is preferably defined by a linear slant surface as shown in FIG. 1 that is so shaped as to extend outward gradually from the bottom to the top, or a curved slant surface that is so shaped as to extend outward gradually from the bottom to the top, or a rectangular surface.

Thus, in the package embodying the invention, firstly, the light-emitting element 55 is mounted on the mounting portion 51a and is then electrically connected to the conductor layer 57 through the conductive adhesive 58. Then, the light-emitting element 55 is covered with a light-transmitting member 53. Whereupon, the light-emitting apparatus 50 is realized.

In the invention, the light-transmitting member 53 is made of light-transmitting resin such as epoxy resin or silicone resin. The light-transmitting member 53 is formed by charging the resins material inside the reflection member 52 by an injector such as a dispenser so as to cover the light emitting element 55, followed by performing heat-hardening thereon in an oven or the like equipment.

Note that the light-transmitting member 53 may contain fluorescent materials capable of performing wavelength conversion on the light emitted from the light-emitting element 55.

Moreover, as shown in FIG. 2, the upper surface of the light-transmitting member 53 is preferably so shaped as to rise convexly. This makes it possible to make approximations on the lengths of the optical paths along which the light beams emitted from the light-emitting element 55 in various directions are individually transmitted through the light-transmitting member 53, and thereby avoid unevenness in radiation intensity effectively.

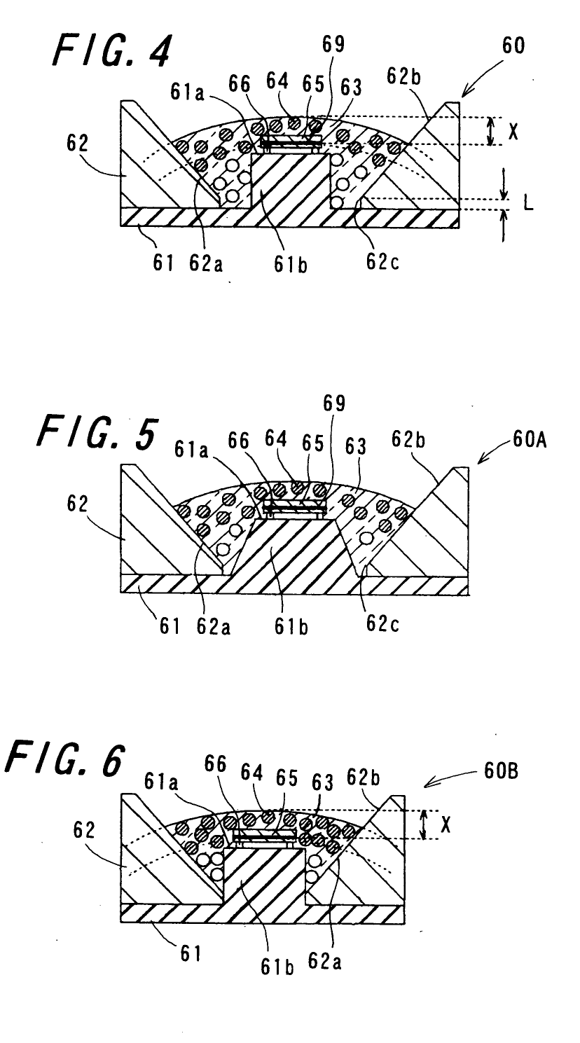

FIG. 4 is a sectional view showing the light-emitting apparatus 60 according to a third embodiment of the invention. The light-emitting apparatus 60 is mainly constituted of a base body 61; a reflection member 62 serving as a frame body; and a light-transmitting member 63 which contains fluorescent materials 64. The light-emitting apparatus 60 allows light emitted from a light-emitting element 65 to radiate out with directivity.

In the invention, the base body 61 is made of ceramics such as alumina ceramics, aluminum nitride sintered body, mullite sintered body, or glass ceramics, or a resin material such as epoxy resin. The base body 61 has, on its upper surface, a mounting portion 61a for mounting thereon the light-emitting element 65. The mounting portion 61a in so formed as to protrude from the upper surface. In a case where the base body 61 is made of a ceramic material, in the same manner of the above mentioned embodiment of the invention, it is preferable that the ceramic crystal grains range in average particle diameter from 1 μm to 5 μm.

The mounting portion 61a is formed on the upper surface of the base body 61 as follows. At first, a convexity 61b is prepared with use of ceramics such as alumina ceramics, aluminum nitride sintered body, mullite sintered body, or glass ceramics, or a metal material such as an Fe—Ni—Co alloy or Cu—W alloy, or a resin material such as epoxy resin. Then, the convexity 61b is attached onto the upper surface of the base body 61 with use of a bonding material such as a brazing filler material or an adhesive, thereby realizing the mounting portion 61a. In the alternative, the convexity 61b may be formed integrally with the upper surface of the base body 61, or the convexity 61b made of the aforementioned material may be fitted into a through hole drilled at the center of the base body 61 such that its upper part protrudes from the upper surfaces of the base body 61.

Preferably, the convexity 61b and the base body 61 are made of the same material. This makes it possible to minimize the difference in thermal expansion between the mounting portion 61a and the base body 61. Thus, it never occurs that the light-emitting element 65 is positionally deviated due to occurrence of distortion in the mounting portion 61a, and reduction of the light emission efficiency can accordingly be avoided.

More preferably, the convexity 61b and the base body 61 are formed integrally with each other. This eliminates the need to interpose a building material between the convexity 61b and the base body 61, which leads to excellent dissipation of heat emanating from the light-emitting element 65 into the base body 61.

For example, a one-piece structure of the convexity 61b and the base body 61 is realized by stacking together ceramic green sheets to be formed into the convexity 61b and the base body 61, followed by firing them at one time, or realized by performing metal processing such as cutting, or realized by molding resin by means of injection molding or the like method.

Moreover, as the light-emitting apparatus 60A according to a fourth embodiment of the invention shown in FIG. 5, the convexity 61b is preferably so shaped that its side surfaces inclinedly extend outward gradually with increasing proximity to the base body 61. This makes it possible to enhance diffusivity of heat emanating from the light-emitting element 65, and to allow light to be efficiently reflected upward from the side surface of the protruding mounting portion 61a. As a result, the light emission efficiency of the light-emitting element 65, as well as the wavelength conversion efficiency of the fluorescent materials 64, can be increased, and besides, the light emitted from the light emitting element 65 or the fluorescent materials 64 can be reflected upward efficiently. Hence, light output can be achieved with high radiation intensity for a longer period of time.

On the mounting portion 61a is folded an electrical connection pattern serving as a wiring conductor (not shown) used for electrical connection of the light-emitting element 65. The electrical connection pattern is led out, through a wiring layer (not shown) formed within the base body 61, to the outer surface of the light-emitting apparatus. Upon this led-out part being connected to an external electric circuit board, electrical connection is established between the light-emitting element 65 and the external electric circuit.

The examples of means for connecting the light-emitting element 65 to the electrical connection pattern include a wire-bonding connecting method, and a flip-chip bonding method whereby connection is established by using an electrode 66 such as a solder bump on the lower surface of the light-emitting element 65. The flip-chip bonding method is more desirable for connection. By adopting such methods, the electrical connection pattern can be disposed immediately below the light-emitting element 65. This eliminates the need to secure an extra spare for the electrical connection pattern around the light-emitting element 65 on the upper surface of the base body 61. Hence, it never occurs that the light emitted from the light-emitting element 65 is absorbed in the space of the base body 61 secured for the electrical connection pattern. An undesirable decrease in the on-axis luminous intensity can accordingly be avoided effectively.

For example, the electrical connection pattern is realized by forming metallized layer made of powder of a metal such as W, Mo, Cu, or Ag on the surface of or inside the base body 61, or realized by burying a lead terminal made of a metal such as an Fe—Ni—Co alloy in the base body 61, or realized by fitting an input/output terminal formed of an insulator carrying a wiring conductor into a through hole drilled in the base body 61.

It is preferable that the electrical connection pattern has its exposed surface coated with a highly corrosion-resistant metal such as Ni or gold (Au) in the thickness ranging from 1 to 20 μm. This makes it possible to protect the electrical connection pattern against oxidative corrosion effectively, and to strengthen the connection between the light-emitting element 65 and the electrical connection pattern. Accordingly, the exposed surface of the electrical connection pattern should preferably be coated with for example a 1 to 10 μm-thick Ni plating layer and a 0.1 to 3 μm-thick Au plating layer successively by the electrolytic plating method or electroless plating method.

Moreover, like the second embodiment of the invention, onto the upper surface of the base body 61 is attached the reflection member 62 with use of a bonding material such as solder, a brazing filler material such as Ag brazing filler, or an epoxy-resin adhesive. The reflection member 62 has a through hole 62a drilled at the center thereof, and has its inner peripheral surface shaped into a reflection surface 2b for reflecting light emitted from the light-emitting element 65.

The reflection surface 62b is formed in the same manner of the second embodiment of the invention, and the description will be omitted.

Moreover, like the second embodiment of the invention, an arithmetic average roughness Ra at the top of the reflection surface 62b is preferably adjusted to fall in a range of 0.004 to 4 μm. This makes it possible to allow the light emitted from the light-emitting element 65 or the fluorescent materials 64 to be satisfactorily reflected from the reflection surface 62b.

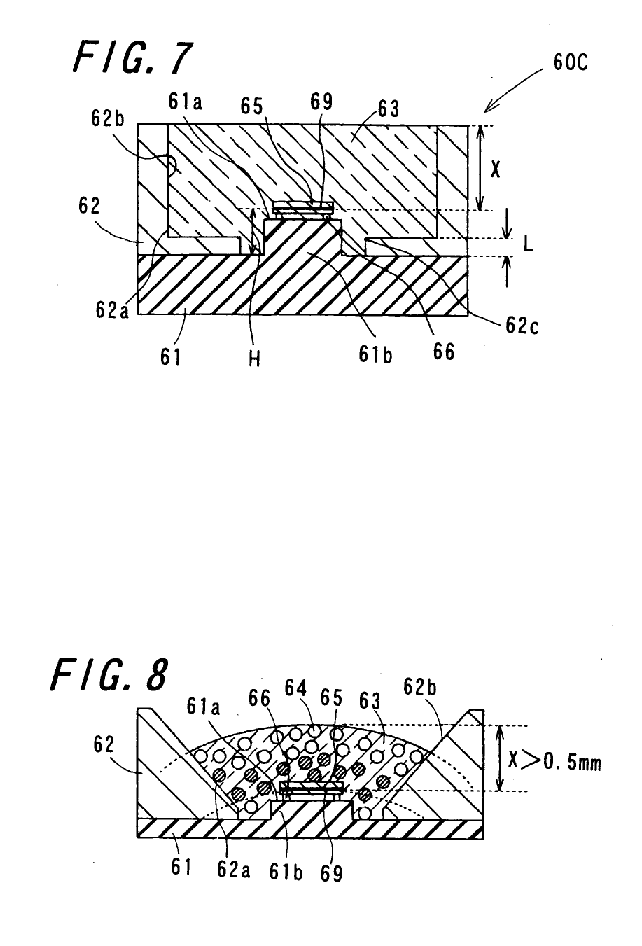

In the reflection surface 62b, for example, its vertical sectional profile is preferably defined by a linear slant surface that is so shaped as to extend outward gradually from the bottom to the top, as the light-emitting apparatus 60, 60A and 60B according to third to fifth embodiments of the invention shown in FIGS. 4 to 6, or a curved slant surface that is so shaped as to extend outward gradually from the bottom to the top, or a rectangular surface as the light-emitting apparatus 60C according to the sixth embodiment of the invention shown in FIG. 7.

Although the reflection member 62 may be attached to any location of the base body 61 except for the area in which the convexity 61b is formed, it is preferably attached around the light-emitting element 65 with desired surface accuracy. Specifically, for example, the reflection member 2 is attached such that its reflection surfaces 62b disposed on both sides of the light-emitting element 65 are symmetrical with each other, when viewed in the vertical section of the light-emitting apparatus. In this way, not only it is possible to allow the light emitted from the light-emitting element 65 to radiate out directly after being wavelength-converted by the fluorescent materials 64 properly, but it is also possible to allow the light emitted laterally or in other directions from the light-emitting element 65, or the light emitted downwardly from the fluorescent materials 64 to be reflected evenly from the reflection surface 62b. The on-axis luminous intensity, brightness, color rendering, and the like characteristics can accordingly be improved effectively.

Especially, as shown in FIG. 6, the smaller the interval between the reflection member 62 and the convexity 61b, the greater the effects described just above. Thus, by forming the reflection member 62 so as to surround the convexity 61b having the mounting portion 61a, it is possible to reflect as much light as possible, thereby attaining higher and higher on-axis luminous intensity.

Moreover, the light-emitting section 69 of the light-emitting element 65 mounted on the mounting portion 61a is higher in level than a lower end 62c of the reflection surface 62b. That is, the level of the light-emitting section of the light-emitting element 65 with respect to the upper surface of the base body 61 is greater than a thickness L of that part of the reflection member 62 which lies near the lower opening of the through hole 62a. This makes it possible to effectively prevent diffuse reflection of light emitted from the light-emitting element 65 resulting from a burr, etc. that appears at the lower end 62c of the reflection surface 62b during processing of the reflection member 62, or part of a brazing filler material that spreads out at the time when the reflection member 62 is joined to the base body 61. Another advantage is that the light emitted from the light-emitting element 65 can be applied to a multiplicity of fluorescent materials 64 existing near the surface of the light-transmitting member 63. The wavelength conversion efficiency can accordingly be enhanced significantly.

In the invention, the light-transmitting member 63 is made of light-transmitting resin such as epoxy resin or silicone resin containing the fluorescent materials 64 capable of performing wavelength conversion on the light emitted from the light-emitting element 65. The light-transmitting member 63 is formed by charging the material inside the reflection member 2 by an injector such as a dispenser so as to cover the light-emitting element 65, followed by performing heat-hardening thereon in an oven or the like equipment. Thus, it is possible to take out light having a desired wavelength spectrum by subjecting the light emitted from the light-emitting element 65 to wavelength conversion effected by the fluorescent materials 64.

Moreover, the light-transmitting member 63 is so disposed that an interval X between its upper surface and the light-emitting section 69 of the light-emitting element 65 ranges from 0.1 to 0.5 mm. In this way, the light emitted from the light-emitting element 65 can be wavelength-converted with high efficiency by the fluorescent materials 64 contained in a part of the light-transmitting member 63 of predetermined thickness which is located above the light-emitting section 69 of the light-emitting element 65, and then the wavelength-converted light is allowed to exit directly from the light-transmitting member 63 without suffering from disturbance caused by the fluorescent materials 64. As a result, the light-emitting apparatus is capable of providing increased radiation intensity and excellent optical characteristics such as on-axis luminous intensity, brightness, and color rendering.

If the interval X between the light-emitting section 69 of the light-emitting element 65 and the surface of the light-transmitting member 63 is longer than 0.5 mm as shown in FIG. 8, although, of the fluorescent materials 64, the once existing closer to the light-emitting element 65 (hatched fluorescent materials 64) are capable of effecting wavelength conversion through direct excitation of light emitted from the light-emitting element 65, it is difficult to allow the wavelength-converted light to exit directly from the light-transmitting member 63. That is, since the travel of light is disturbed by the fluorescent materials 64 existing near the surface of the light-transmitting member 63 (the ones other than the hatched fluorescent materials 64 in FIG. 8), it will become difficult to attain satisfactory external on-axis luminous intensity.

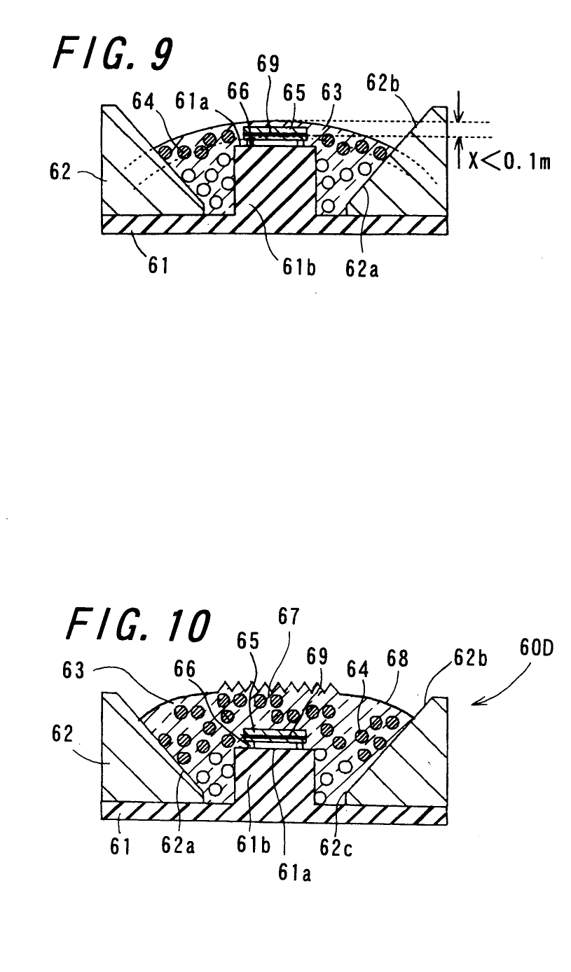

By contrast, as shown in FIG. 9 if the interval X between the light-emitting section 69 of the light-emitting element 65 and the surface of the light-transmitting member 63 is shorter than 0.1 mm, it will be difficult to achieve efficient wavelength conversion for the light emitted from the light-emitting element 65. In this case, there is an undesirable increase in the quantity of low-luminosity light of certain wavelength that is transmitted through the light-transmitting member 63 without undergoing wavelength conversion, with the result that satisfactory optical characteristics such as on-axis luminous intensity, brightness, and color rendering cannot be attained.

Moreover, such as the light-emitting apparatus 60D of the seventh embodiment of the invention known in FIG. 10, the light-transmitting member 63 is preferably so designed that its center portion is larger in arithmetic average surface roughness than its outer peripheral portion. This helps reduce the difference in radiation intensity between the light exiting from the center portion and the light exiting from the outer peripheral portion in the light-transmitting member 63. Specifically, the light that has been emitted from the light-emitting element 65 and then radiated directly from the center portion of the light-transmitting member 63's surface without being reflected from the reflection member 2 or the like has high intensity. This light is appropriately scattered by a rough surface 67 in the center portion of the light-transmitting member 63's surface so that its intensity may be slightly decreased. In this way, the intensity of the light which is emitted from the center portion of the surface of the light-transmitting member can be approximated to the low intensity of the light that has been radiated from the outer peripheral portion of the light-transmitting member 63's surface after being reflected from the reflection member 2; wherefore the difference in radiation intensity between the center portion and the outer peripheral portion in the light-transmitting member 63 can be reduced. As a result, the light-emitting apparatus is capable of emitting uniform light in a wider area. Moreover, it is possible to avoid glare, i.e. a phenomenon which stings human eyes, resulting from concentration of radiation intensity in certain part of the light-emitting surface. Detrimental effects on human eyes can thus be minimized.

It is preferable that, on the surface of the light-transmitting member 63, the center portion exhibits an arithmetic average roughness of 0.5 μm or above, whereas the outer peripheral portion exhibits an arithmetic average roughness of 0.1 μm or below. In this way, the radiation intensity as seen on the surface of the light-transmitting member 63 can be made as uniform as possible and satisfactory.

In a case where the light-transmitting member 63 has its area ranging from the center portion to the outer peripheral portion made as a smooth surface, in the center portion, since the interval between the light-emitting element 65 and the light-transmitting member 63 is short, it follows that transmission loss is low and the radiation intensity is high. On the other hand, at the outer peripheral portion of the light-transmitting member 63, since the light emitted from the light-emitting element 65 exits out of the light-emitting apparatus after being reflected from the reflection member 2, it follows that the optical path lengthens and the radiation intensity is low due to reflection loss occurring in the reflection member. As a result, there arises a great difference in light intensity between the center portion and the outer peripheral portion in the light-transmitting member 63, and this leads to unevenness in color of the light emitted from the light-emitting apparatus and to unevenness in illumination distribution on a to-be-irradiated surface. In view of the foregoing, by designing the light-transmitting member 63 such that the center portion is larger in arithmetic average surface roughness than the outer peripheral portion, it is possible to effectively avoid unevenness in color of the light emitted from the light-emitting apparatus and unevenness in illumination distribution on a to-be-irradiated surface.

For example, such a rough surface 67 is obtained by roughing the surface of the light-transmitting member 63 through spraying of ceramic powder or the like thereon from above the light-emitting apparatus, with the outer edge of the surface kept masked by a metal film.

Moreover, as shown in FIG. 4, the upper surface of the light-transmitting member 63 is preferably so shaped as to rise convexly. In this way, the interval between the light-emitting section 69 and the surface of the light-transmitting member 63 can be kept in a range from 0.1 to 0.5 mm. Thus, even if light is emitted obliquely upwardly from the light-emitting element 65, the radiation intensity can be increased.

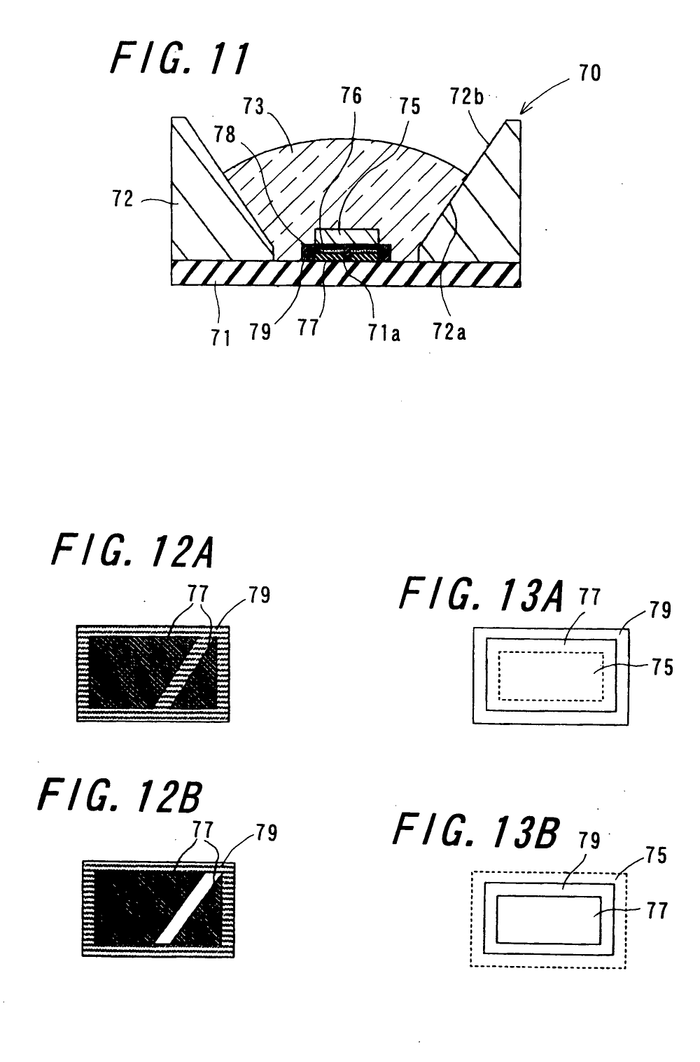

FIG. 11 is a sectional view showing a light-emitting apparatus 70 according to an eighth embodiment of the invention. The light-emitting apparatus 70 is mainly constituted of a base body 71, reflection member 72 serving as a frame body, a light-transmitting member 73, a conductive layer 77 and convexity 79.

A package for housing a light-emitting element embodying the invention includes the base body 71; the frame-like reflection member 72; and the conductor layer 77. The base body 71 has, at the center of its upper surface, a mounting portion 71a for mounting thereon a light-emitting element 75. The reflection member 72 is disposed at the outer periphery of the upper surface of the base body 71 so as to surround the mounting portion 71a. The conductor layer 77 is formed on the mounting portion 71a. The light-emitting element 75 is electrically connected to the conductor layer 77 via a conductive adhesive 78. Around the conductor layer 77 is formed a convexity 79 made of an insulating material. Note that, a wiring conductor is provided in the package. The wiring conductor has one end formed on the upper surface of the base body 71 and electrically connected to an electrode of the light-emitting element 75, and another end led out to a side surface or lower surface of the base body 71. The one end of the wiring conductor is designed as the conductor layer 77.

In the invention, the base body 71 is made of ceramics such as alumina ceramics, aluminum nitride sintered body, mullite sintered body, or glass ceramics, or a resin material such as epoxy resin. The base body 71 has, on its upper surface, the mounting portion 71a for mounting thereon the light-emitting element 75. Moreover, in a case where the base body 71 is made of ceramics, like the above embodiment of the invention, it is preferable that ceramic crystal grains range in average particle diameter from 1 to 5 μm.

Formed on the mounting portion 71a is the conductor layer 77 to which the light-emitting element 75 is electrically connected, for fixedly mounting the light-emitting element 75 on the base body 71. The conductor layer 77 is led out, through a wiring conductor (not shown) formed within the base body 71, to the outer surface of the light-emitting apparatus. Upon this part led out to the outer surface of the light-emitting apparatus being connected to an external electric circuit board, electrical connection is established between the light-emitting element 75 and the external electric circuit.

In a case where the base body 71 is made of ceramics, on the upper surface of the base body 71 is formed the conductor layer 77 by firing a metal paste of W, Mo—Mn, Cu, or Ag to be formed into the conductor layer 77 at a high temperature. On the other hand, in a case where the base body 71 is made of a resin material, a molded lead terminal made of Cu or Fe—Ni alloy is fixedly arranged within the base body 71. The conductor layer 77 is formed in that way.

The convexity 79 is formed around the conductor layer 77. In a case where the base body 71 is made of ceramics, for example, the convexity 79 is formed by print-coating a ceramic paste predominantly composed of a material used for forming the base body 71, followed by firing the ceramic paste at a high temperature together with the metal paste to be formed into the conductor layer 77. On the other hand, in a case where the base body 71 is made of a resin material, for example, the convexity 79 is formed by means of die-molding, using the same material as that used for the base body 71, concurrently with the formation of the base body 71. Note that the convexity 79 does not necessarily have to be made of the same material as that used for the base body 71, but may be made of any other material.

As described above, around the conductor layer 77 is formed the convexity 79 made of an insulating material. Therefore, with the convexity 79, the conductive adhesive 78 can be prevented from spreading outwardly of the conductor layer 77; wherefore the conductive adhesive 78 has a uniform thickness. The light-emitting element 75 can accordingly be mounted on the conductor layer 77 horizontally. As a result, light is emitted from the light emitting element 75 at a desired exiting angle, and the emitted light is then reflected from the reflection member 72 at a desired radiation angle so as to radiate out properly, whereby making it possible to increase the radiation intensity of the light emitted from the light-emitting apparatus.

Moreover, since the light-emitting element 75 is mounted on the conductor layer 77 horizontally, it follows that the heat emanating from the light-emitting element 75 can be evenly transmitted though the conductive adhesive 78 and the base body 71, and eventually dissipated to the outside with high efficiency. As a result, the temperature of the light-emitting element 75 can be maintained with stability; wherefore the radiation intensity of the light emitted from the light-emitting element 75 can be maintained high with stability.

Further, the light emitted from the light-emitting element 75 can be effectively prevented from being applied to the conductive adhesive 78 by the convexity 79. Hence, it never occurs that the light emitted from the light-emitting apparatus is absorbed by the conductive adhesive 78, and thus an undesirable decrease in the radiation intensity, brightness, and color rendering can be avoided effectively. There will thus be provided the light-emitting apparatus that offers high radiation intensity and excellent light emission characteristics.

Note that the convexity 79 may be formed either in such a way as to cover the outer periphery of the conductor layer 77, or in such a way as not to cover the outer periphery. Moreover, in a case where the conductor layer 77 is formed in plural, the convexity 79 may be formed throughout the periphery of each conductor layer has shown in FIG. 12A, or formed around the group of a plurality of conductor layers 7 as shown in FIG. 12B.

As shown in FIG. 13A, the conductor layer 77 may be so configured that its exposed part lies outside the outer periphery of the light-emitting element 75. More preferably, as shown in FIG. 13B, the conductor layer 77 is so configured that its exposed part lies inside the outer periphery of the light-emitting element 75. In this way, the conductive adhesive 78 for joining together the conductor layer 77 and the light emitting element 75 can be prevented from being exposed off the area between the conductor layer 77 and the light-emitting element 75; wherefore the light emitted from the light-emitting element 75 can be prevented from being applied to the conductive adhesive 78 quite effectively. As a result, it never occurs that the light emitted from the light-emitting element 75 is absorbed by the conductive adhesive 78 or reflected therefrom as light exhibiting low radiation intensity. The radiation intensity of the light emitted from the light-emitting apparatus can accordingly be maintained high, and excellent brightness and color rendering can be attained.

Another advantage is that, even if the light emitted from the light-emitting element 75 is ultraviolet light, the conductive adhesive 78 will not suffer from quality degradation. Thus, the strength of bonding between the conductor layer 77 and the light-emitting element 75 can be kept sufficiently high; wherefore the steadfast fixation between the conductor layer 77 and the light-emitting element 75 can be maintained for a longer period of time. As a result, the electrical connection between the electrode 76 of the light-emitting element 75 and the conductor layer 77 can be ensured for a longer period of time. The light-emitting apparatus can accordingly offer a longer service life.

In addition, the convexity 79 is so shaped that its side surfaces inclinedly extend outward gradually with increasing proximity to the base body 71. Therefore, this makes air present at a corner portion formed between the side surface of the convexity 79 and the upper surface of the base body 71 easy to drain, and prevents the air from remaining at the corner portion. Accordingly, it is possible to effectively prevent that a void is formed in the conductive adhesive 78 and the light-transmitting member 73 and peeling or a crack is caused by expansion of air in the void due to change in temperature or the like. In addition, it is possible to well reflect light on the outer inclined side surfaces of the convexity 79 upward, and to improve the light emission efficiency.

It is preferable that the convexity 79 exhibits reflectivity of 60% or above with respect to the light emitted from the light-emitting element 75 and the fluorescent materials contained in the light-transmitting member 73. In this way, the light emitted from the light-emitting element 75 or the fluorescent materials can be prevented more effectively from being absorbed by the convexity 79 or reflected therefrom as light exhibiting low radiation intensity The radiation intensity of the light emitted from the light-emitting apparatus can accordingly be maintained extremely high. If the reflectivity of the convexity 79 is less than 60%, the quantity of light emitted from the light-emitting element 75 or the fluorescent materials that may be absorbed by the convexity 79 will be increased, which results in an undesirable decrease in the radiation intensity or the light emitted from the light-emitting apparatus.

Connection of the light-emitting element 75 is made, at the electrode 76 formed on the lower surface thereof, through the conductive adhesive 78 such as an Ag paste or gold (Au)-tin (Sn) solder.

It is preferable that, like the second embodiment of the invention, the conductor layer 77 has its exposed surface coated with a highly corrosion resistant metal such as Ni or Au in the thickness ranging from 71 to 20 μm.

Onto the upper surface of the base body 71 is attached the reflection member 72 with use of a bonding material such as solder, a brazing filler material such as Ag brazing filler, or an epoxy-resin adhesive. The reflection member 72 has a through hole 72a drilled at the center thereof. Preferably, the inner peripheral surface of the through hole 72a is shaped into a reflection surface 72b for reflecting light emitted from the light-emitting element 75 and the fluorescent materials.

The reflection surface 72b is formed in the same manner as the second embodiment of the invention and the description will be omitted.

Moreover, like the second embodiment of the invention, an arithmetic average roughness Ra at the top of the reflection surface 72b is preferably adjusted to fall in a range of 0.004 to 4 μm. This makes it possible to allow the light emitted from the light-emitting element 75 and the fluorescent materials to be satisfactorily reflected from the reflection surface 72b.

In the reflection surface 72b, for example, its vertical sectional profile is preferably defined by a linear slant surface that is so shaped as to extend outward gradually from the bottom to the top as shown in FIG. 11, or a curved slant surface that is so shaped as to extend outward gradually from the bottom to the top, or a rectangular surface.

Thus, in the package embodying the invention, firstly, the light-emitting element 75 is mounted on the mounting portion 71a and is then electrically connected to the conductor layer 77 through the conductive adhesive 78. Then, the light-emitting element 75 is covered with a light-transmitting member 73. Whereupon, the light-emitting apparatus 70 is realized.

In the invention, the light-transmitting member 73 is made of light-transmitting resin such as epoxy resin or silicone resin. The light transmitting member 73 is formed by charging the resin material inside the reflection member 72 by an injector such as a dispenser so as to cover the light-emitting element 75, followed by performing heat-hardening thereon in an oven or the like equipment.

Note that the light-transmitting member 73 may contain fluorescent materials capable of performing wavelength conversion on the light entitled from the light-emitting element 75.

Moreover, As shown in FIG. 11, the upper surface of the light-transmitting member 73 is preferably so shaped as to rise convexly. This makes it possible to make approximations on the lengths of the optical paths along which the light beams omitted from the light-emitting element 75 in various directions are individually transmitted through the light-transmitting member 73, and thereby avoid unevenness in radiation intensity effectively.

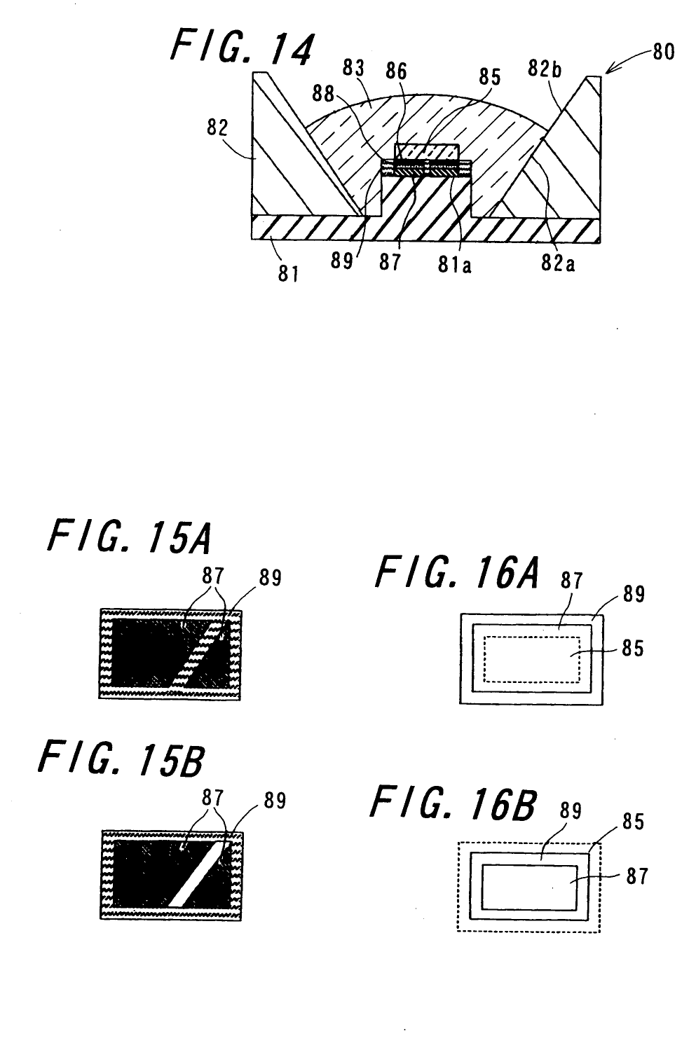

FIG. 14 is a sectional view showing a light-emitting apparatus 80 according to a ninth embodiment of the invention. The light-emitting apparatus 80 is mainly constituted of a base body 81, a reflection member 82 serving as frame body, a light-transmitting member 83, conductor layer 87 and convexity 89.

A package for housing a light-emitting element embodying the invention includes the base body 81; the frame-like reflection member 82; and the conductor layer 87. The base body 81 has, at a projection 81b protruding from its upper surface, amounting portion 81a for mounting thereon a light-emitting element 85. The reflection member 82 is joined to the upper surface of the base body 81 so as to surround the mounting portion 81a. The inner peripheral surface of the reflection member 82 is shaped into a reflection surface 82b for reflecting light emitted from the light-emitting element 85. The conductor layer 87 is formed on the upper surface of the mounting portion 81a. The light-emitting element 85 is electrically connected to the conductor layer via a conductive adhesive 88. The conductor layer 87 is surrounded by a convexity 89 made of an insulating material. Note that, a wiring conductor is provided in the package. The wiring conductor has one and formed on the upper surface of the base body 81 and electrically connected to an electrode of the light-emitting element 85, and another end led out to a side surface or lower surface of the base body 81. The one end of the wiring conductor is designed as the conductor layer 87.

In this construction, the light having been emitted laterally and obliquely downwardly from the side of the light-emitting element 85 can be reflected from the reflection surface 82b of the reflection member 82 satisfactorily. Thus, the light can be reflected from the reflection member 82 at a desired radiation angle so as to radiate out satisfactorily, without being absorbed by the joint portion between the reflection member 82 and the base body 81 or the surface of the base body 81. As a result, the radiation intensity of the light emitted from the light-emitting apparatus can be maintained high with stability.

Since the projection 81b is formed so that the mounting portion 81a is disposed apart from the upper surface of the base body 81, it follows that insulation is provided between the mounting portion 81a and the lower end of the reflection member 82 without fail. Therefore, this makes it possible to bring the lower end of the reflection member 82 close to the mounting portion, as viewed plane-wise, and thereby allow the light emitted from the light-emitting element 85 to be reflected from the reflection surface of the reflection member 82 more satisfactorily.

Moreover, with the convexity 89 made of an insulating material, the conductive adhesive 88 can be prevented from spreading outwardly of the conductor layer 87; wherefore the conductive adhesive 88 has a uniform thickness. The light-emitting element 85 can accordingly be mounted on the conductor layer 87 horizontally. As a result, light is emitted from the light-emitting element 85 at a desired exiting angle, and the emitted light is then reflected from the reflection member 82 at a desired radiation angle so as to radiate out properly, whereby making it possible to increase the radiation intensity of the light emitted from the light emitting apparatus.

Since the light-emitting element 85 is mounted on the conductor layer 87 horizontally, it follows that the heat emanating from the light-emitting element 85 can be evenly transmitted through the conductive adhesive 88 and the base body 81, and eventually dissipated to the outside with high efficiency. As a result, the temperature of the light-emitting element 85 can be maintained with stability; wherefore the radiation intensity of the light emitted from the light-emitting element 85 can be maintained high with stability.

Further, the light emitted from the light-emitting element 85 can be effectively prevented from being applied to the conductive adhesive 88 by the convexity 89. Hence, it never occurs that the light emitted from the light-emitting apparatus is absorbed by the conductive adhesive 88, and thus an undesirable decrease in the radiation intensity, brightness, and color rendering can be avoided effectively. There will thus be provided the light-emitting apparatus that offers high radiation intensity and excellent light emission characteristics.

In the invention, the base body 81 is made of ceramics such as alumina ceramics, aluminum nitride sintered body, mullite sintered body, or glass ceramics, or a resin material such as epoxy resin. The base body 81 has, at the projection 81b protruding from its upper surface, the mounting portion 81a for mounting thereon the light-emitting element 85. Moreover, in a case where the base body 81 is made of ceramics, like the above embodiment of the invention, it is preferable that ceramic crystal grains range in average particle diameter from 1 to 5 μm.

The projection 81b may be formed integrally with the base body 81. In this case, the formation is carried out through the well-known ceramic-green-sheet stacking technique, a cutting process, a die-molding process, or the like method.

Further, the projection 81b may also be formed by bonding a rectangular parallelepiped projection 81b portion to the upper surface of the base body 81 by means of brazing, or by using an adhesive. The projection 81b is preferably made of ceramics, resin, an inorganic crystal, a metal, or the like material.

Formed on the mounting portion 81a is the conductor layer 87 to which the light-emitting element 85 is electrically connected, for fixedly mounting the light-emitting element 85 on the base body 81. The conductor layer 87 is led out, through a wiring layer (not shown) formed within the base body 81, to the outer surface of the light-emitting apparatus. Upon this part led out to the outer surface of the light-emitting apparatus being connected to an external electric circuit board, electrical connection is established between the light-emitting element 85 and the external electric circuit.

In a case where the base body 81 is made of ceramics, on the upper surface of the base body 81 is formed the conductor layer 87 by firing a metal paste of W, Mo—Mn, Cu, or Ag at a high temperature. On the other hand, in a case where the base body 81 is made of a resin material, a molded lead terminal made of Cu or Fe—Ni alloy is fixedly arranged within the base body 81. The conductor layer 87 is formed in that way.

The convexity 89 is formed around the conductor layer 87. In a case where the base body 81 is made of ceramics, for example, the convexity 89 is formed by print-coating a ceramic paste predominantly composed of a material used for forming the base body 81, following by firing the ceramic paste at a high temperature together with the metal paste to be formed into the conductor layer 87. On the other hand, in a case where the base body 81 is made of a resin material, for example, the convexity 89 is formed by means of die-molding, using the same material as that used for the base body 81, concurrently with the formation of the base body 81. Note that the convexity 89 does not necessarily have to be made of the same material as that used for the base body 81, but may be made of any other material.

As described above, around the conductor layer 87 is formed the convexity 89 made of an insulating material. Therefore, with the convexity 89, the conductive adhesive 88 can be prevented from spreading outwardly of the conductor layer 87; wherefore the conductive adhesive 88 has a uniform thickness. The light-emitting element 85 can accordingly be mounted on the conductive layer 87 horizontally. As a result, light is emitted from the light-emitting element 85 at a desired exiting angle, and the emitted light is then reflected from the reflection member 82 at a desired radiation angle so as to radiate out properly, whereby making it possible to increase the radiation intensity of the light emitted from the light-emitting apparatus.

Moreover, since the light-emitting element 85 is mounted on the conductor layer 87 horizontally, it follows that the heat emanating from the light-emitting element 85 can be evenly transmitted through the conductive adhesive 88 and the base body 81, and eventually dissipated to the outside with high efficiency. As a result, the temperature of the light-emitting element 85 can be maintained with stability; wherefore the radiation intensity of the light emitted from the light emitting element 85 can be maintained high with stability.

Further, the light emitted from the light emitting element 85 can be effectively prevented from being applied to the conductive adhesive 88 by the convexity 89. Hence, it never occurs that the light emitted from the light-emitting apparatus is absorbed by the conductive adhesive 88, and thus an undesirable decrease in the radiation intensity, brightness, and color rendering can be avoided effectively. There will thus be provided the light-emitting apparatus that offers high radiation intensity and excellent light emission characteristics.

Note that the convexity 89 may be formed so as to cover the outer periphery of the conductor layer 87 entirely circumferentially, or formed alloy the outer edge of the conductor layer 87 without covering it. Moreover, in a case where the conductor layer 87 is formed in plural, the convexity 89 may be formed throughout the periphery of each conductor layer 87 as shown in FIG. 15A, or formed around the group of a plurality of conductor layers 87 as shown in FIG. 15B.

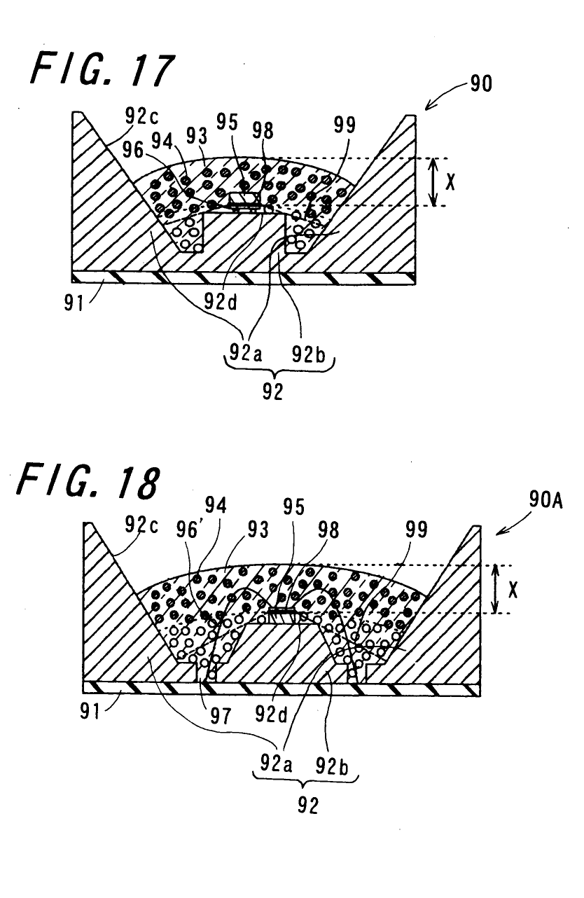

As shown in FIG. 16A, the conductor layer 87 may be so configured that its exposed part lies outside the outer periphery of the light-emitting element 85. More preferably, as shown in FIG. 16B, the conductor layer 87 is so configured that its exposed part lies inside the outer periphery of the light-emitting element 85. In this way, the conductive adhesive 88 for joining together the conductor layer 87 and the light-emitting element 85 can be prevented from being exposed off the area between the conductor layer 87 and the light-emitting element 85; wherefore the light emitted from the light-emitting element 85 can be prevented from being applied to the conductive adhesive 88 quite effectively. As a result, it never occurs that the light emitted from the light-emitting element 85 is absorbed by the conductive adhesive 88 or reflected therefrom as light exhibiting low radiation intensity. The radiation intensity of the light emitted from the light-emitting apparatus can accordingly be maintained high, and excellent brightness and color rendering can be attained. Moreover, by configuring the conductor layer 87 such that its exposed part lies inside the outer periphery of the light-emitting element 85, it is possible to reduce the size of the mounting portion 81a. Correspondingly, the reflection member 82 can be made smaller. The reduction in size of the reflection member 82 allows downsizing of the base body 81, which in turn enables the package as a whole to be made compact.

Another advantage is that, even if the light, emitted from the light emitting element 85 is ultraviolet light, the conductive adhesive 88 will not suffer from quality degradation. Thus, the strength of bonding between the conductor layer 87 and the light emitting element 85 can be kept sufficiently high; wherefore the steadfast fixation between the conductor layer 87 and the light-emitting element 85 can be maintained for a longer period of time. As a result, the electrical connection between the electrode 86 or the light-emitting element 85 and the conductor layer 87 can be ensured for a longer period of time. The light-emitting apparatus can accordingly offer a longer service life.

In addition, the convexity 89 is so shaped that its side surfaces inclinedly extend outward gradually with increasing proximity to the base body 81. Therefore, this makes air present at a corner portion formed between the side surfaces of the convexity 89 and the upper surface of the mounting portion 81a easy to drain, and prevents the air from remaining at the corner portion. Accordingly, it is possible to effectively prevent that a void is formed in the conductive adhesive 88 and the light-transmitting member 83 and peeling or a crack is caused by expansion of air in the void due to change in temperature or the like. In addition, it is possible to well reflect light on the outer inclined side surfaces of the convexity 89 upward, and to improve the light emission efficiency.

Preferably, like the eighth embodiment of the invention, the convexity 89 exhibits reflectivity of 60% or above with respect to the light emitted from the light-emitting element 85 and the fluorescent materials contained in the light-transmitting member 83.

Connection of the light-emitting element 85 is made, at the electrode 86 formed on the lower surface thereof, through the conductive adhesive 88 such as an Ag paste or gold (Au)-tin (Sn) solder.

It is preferable that the conductor layer 87, like the second embodiment of the invention, has its exposed surface coated with a highly corrosion-resistant metal such as Ni or Au in the thickness ranging from 1 to 20 μm.

Onto the upper surface of the base body 81 is attached the reflection member 82 with use of a bonding material such as solder, a brazing filler material such as Ag brazing filler, or an epoxy-resin adhesive. The reflection member 82 has a through hole 82a drilled at the center thereof. Preferably, the inner peripheral surface of the through hole 82a is shaped into a reflection surface 82b for reflecting light emitted from the light-emitting element 85 and the fluorescent materials.

The reflection surface 82b is formed in the same manner as the second embodiment of the invention and the description will be omitted.

Moreover, like the second embodiment of the invention, an arithmetic average roughness Ra at the top of the reflection surface 82b is preferably adjusted to fall in a range of 0.004 to 4 μm. This makes it possible to allow the light emitted from the light-emitting element 85 and the fluorescent materials to be satisfactorily reflected from the reflection surface 82b.

In the reflection surface 82b, for example, its vertical sectional profile is preferably defined by a linear slant surface as shown in FIG. 14 that is so shaped as to extend outward gradually from the bottom to the top, or a curved slant surface that is so shaped as to extend outward gradually from the bottom to the top, or a rectangular surface.

Thus, in the package embodying the invention, firstly, the light-emitting element 85 is mounted on the mounting portion 81a and is then electrically connected to the conductor layer 87 through the conductive adhesive 88. Then, the light-emitting element 85 is covered with a light-transmitting member 83. Whereupon, the light-emitting apparatus 80 is realized.

In the invention, the light-transmitting member 83 is made of light-transmitting resin such as epoxy resin or silicone resin. The light transmitting member 83 is formed by charging the resin material inside the retention member 82 by an injector such as a dispenser so as to cover the light-emitting element 85, followed by performing heat-hardening thereon in an oven or the like equipment.

Note that the light-transmitting member 83 may contain fluorescent materials capable of performing wavelength conversion on the light emitted from the light-emitting element 85.

Moreover, as shown in FIG. 14, the upper surface of the light-transmitting member 83 is preferably so shaped as to rise convexly. This makes it possible to make approximations on the lengths of the optical paths along which the light beams emitted from the light-emitting element 85 in various directions are individually transmitted through the light-transmitting member 83, and thereby avoid unevenness in radiation intensity effectively.

FIG. 17 is a sectional view showing a light-emitting apparatus 90 according to a tenth embodiment of the invention. The light-emitting apparatus 90 is mainly constituted of a base body 91, a reflection member 92, a light-transmitting member 93 which contains fluorescent materials 94 and a light-emitting element 95. The light-emitting apparatus 90 allows light emitted from the light-emitting element 95 to radiate out with directivity.

In the invention, the base body 91 is made of ceramics such as alumina ceramics, aluminum nitride sintered body, mullite sintered body, or glass ceramics, or a resin material such as epoxy resin, or a metal material such as an Fe Ni—Co alloy, Cu—W, or Al. The base body 91 has a function of fixedly mounting thereon the reflection member 92. The reflection member 92 has, on an upper principal surface thereof, a mounting portion 92d for mounting thereon the light-emitting element 95. Moreover, in a case where the base body 91 is made of ceramics, like the above embodiment of the invention, it is preferable that ceramic crystal grains range in average particle diameter from 1 to 5 μm.

Onto the upper surface of the base body 91 is attached the reflection member 92 with use of a bonding material such as solder, a brazing filler material such as an Ag brazing filler, or an epoxy-resin adhesive. The reflection member 92 has, at the center of its upper principal surface, a convex mounting portion 92b for mounting thereon the light-emitting element 95. Also, the reflection member 92 has, at the outer periphery of its upper principal surface, a side wall portion 92a formed so as to surround the mounting portion 92b, the inner peripheral surface of side wall portion which is shaped into a reflection surface 92c for reflecting light emitted from the light-emitting element 95. In this way, not only it is possible to allow the light emitted from the light-emitting element 95 to radiate out directly after being wavelength-converted by the fluorescent materials 4 properly, but it is also possible to allow the light emitted laterally or in other directions from the light emitting element 95, or the light emitted downwardly from the fluorescent materials 94 to be reflected evenly from the reflection surface 92c. The on-axis luminous intensity, brightness, color rendering, and the like characteristics can accordingly be improved effectively.

The reflection member 92 is made of ceramics such as alumina ceramics, aluminum nitride sintered body, mullite sintered body, or glass ceramics, or a resin material such as epoxy resin, or a metal material such as an Fe—Ni—Co alloy, Cu—W, or Al. The formation is carried out through a cutting process, a die-molding process, or the like. The reflection surface 92c is formed by performing cutting or die-molding on the inner peripheral surface of the side wall portion 92a of the reflection member 92, or formed by coating the inner peripheral surface of the side wall portion 92a with a metal thin film of a high reflectivity metal such as Al, Ag, Au, platinum (Pt), titanium (Ti), chromium (Cr), or Cu by means of plating or vapor deposition.

In a case where the reflection surface 92c is made of a metal, such as Ag or Cu, that is susceptible to discoloration resulting from oxidation, in the same manner as the second embodiment of the invention, it is preferable to laminate on its surface for example a 1 to 10 μm-thick Ni plating layer and a 0.1 to 3 μm-thick Au plating layer successively by the electrolytic plating method or electroless plating method. This makes it possible to improve the corrosion resistance of the reflection surface 92c.

Moreover, like the second embodiment of the invention, an arithmetic average roughness Ra at the top of the reflection surface 92c is preferably adjusted to fall in a range of 0.004 to 4 μm. This makes it possible to allow the light emitted from the light-emitting element 95 and the fluorescent materials 94 to be satisfactorily reflected from the reflection surface 92c.

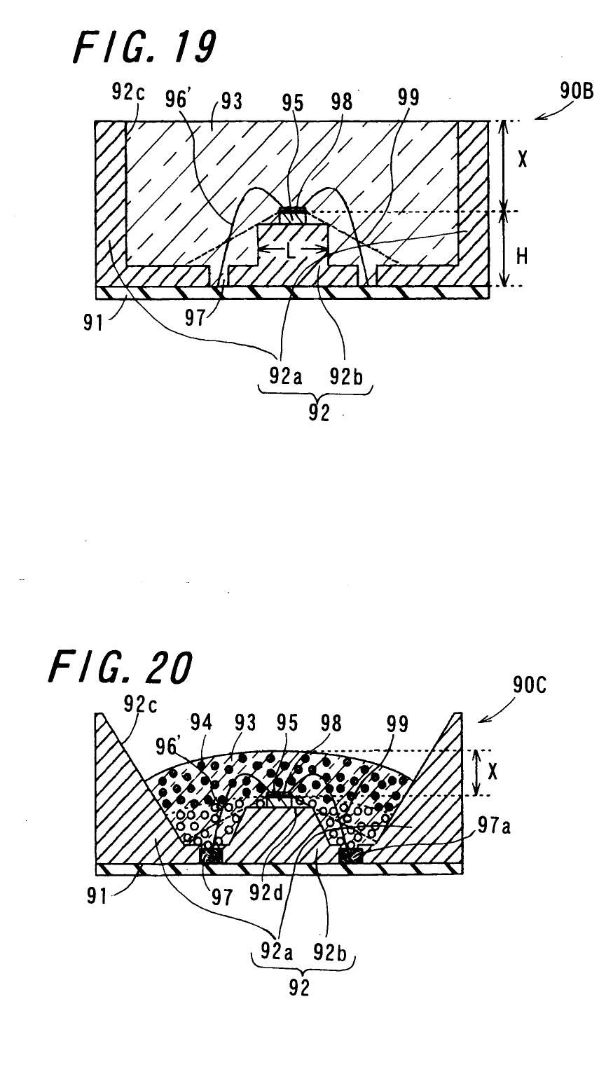

In the reflection surface 92c, for example, its vertical sectional profile is preferably defined by a linear slant surface that is so shaped as to extend outward gradually from the bottom to the top, as the light-emitting apparatuses 90 and 90A according to tenth and eleventh embodiments of the invention shown in FIGS. 17 and 18, or a curved slant surface that is so shaped as to extend outward gradually from the bottom to the top, or a rectangular surface as the light-emitting apparatus 90B according to the twelfth embodiment of the invention shown in FIG. 19.

In the invention, the reflection surface 92c has its lower end located on or below an optical path line 99 connecting the light-emitting section 98 lying at the end of the light-emitting element 95 and the corner between the upper surface 92d and the side surface of the mounting portion 92b. This allows the direct light emitted laterally or downwardly from the light-emitting element 95 to be efficiently reflected from the reflection surface 92c, thereby attaining significantly high radiation light intensity.

The light-emitting element 95 is mounted on the upper surfacer 92d of the mounting portion 92b, and its electrode is electrically connected to an electrode pad formed on the upper surface 92d of the mounting portion 92b, or an electrode pad composed of part of a wiring conductor formed on the upper surface of the base body 91. The electrode pad is led out, through the wiring conductor (not shown) formed within the base body 91 and the reflection member 92, to the outer surface of the light-emitting apparatus 90 (a side surface or a lower surface of the base body 91). Upon this led-out part being connected to an external electric circuit board. Thus, electrical connection is established between the light-emitting element 95 and the external electric circuit.

For example, such an electrode pad is realized by forming a metallized layer made of powder of a metal such as W, Mo, Cu, or Ag on the surface of or inside the base body 91 or the reflection member 92, or realized by burying a load terminal made of a metal such as an Fe—Ni—Co alloy in the base body 91 or the reflection member 92, or realized by fitting an input/output terminal formed of an insulator carrying a wiring conductor into a through hole drilled in the base body 91 or the reflection member 92.

It is preferable that the electrode pad and the wiring conductor have their exposed surfaces coated with a highly corrosion-resistant metal such as Ni or gold (Au) in the thickness ranging from 1 to 20 μm. This makes is possible to protect the electrode pad and the wiring conductor against oxidative corrosion effectively, and to strengthen the connection between the light-emitting element 95 and the electrode pad. Accordingly, the exposed surfaces of the electrode pad and the wiring conductor should preferably be coated with for example a 1 to 10 μm-thick Ni plating layer and a 0.1 to 3 μm-thick Au plating layer successively by the electrolytic plating method or electroless plating method.

Moreover, the mounting portion 92b may be configured differently. In FIG. 17, the mounting portion 92b has its side surfaces shaped perpendicularly to the base body 91. In FIG. 18, the side surfaces are so shaped as to broaden gradually toward the base body 91. In the latter case, heat emanating from the light-emitting element 95 can be efficiently transmitted downwardly from the mounting portion 92b, thereby improving the heat-dissipation property of the light-emitting element 95. The light-emitting element 95 can be maintained in good operating condition.

In a case where the reflection member 92 is formed of an insulating material, as shown in FIG. 17, electrical connection between the light-emitting element 95 and the electrode pad formed on the upper surface 92d of the mounting portion 92b is established through the flip-chip bonding method such as metal-bump (electrical connecting means 96) bonding. Moreover, although not shown in FIG. 17, if the electrode pad is formed on the upper surface of the reflection member 92, the wire bonding method such as gold-wire (electrical connecting means 96′) bonding may be adopted. The flip-chip bonding method is more desirable for connection. By adopting it, the electrode pad can be disposed immediately below the light-emitting element 95. This eliminates the need to secure an extra space for the electrical connection pattern around the light-emitting element 95 on the upper surface of the base body 91. Hence, it never occurs that the light emitted from the light-emitting element 95 is absorbed in the space of the base body 91 secured for the electrical connection pattern. An undesirable decrease in the on-axis luminous intensity can accordingly be avoided effectively.

Moreover, in a case where the base body 91 is formed of an insulating material, as shown in FIG. 18, a through hole 97 is created around the mounting portion 92b of the reflection member 92 formed of an insulating material or a metal material. The through hole 97, which is drilled all the way through from the upper principal surface to the lower principal surface of a part of the reflection member 92, is located below the optical path line. Preferably, the electrode of the light-emitting element 95 and the wiring conductor formed on the upper surface of the base body 91 are electrically connected to each other by means of a wire (electrical connecting means 96′) inserted through the through hole 97. In this way, direct light emitted from the light-emitting element 95 is reflected from the reflection surface 92c above the through hole 97 drilled in the reflection member 92 for inserting thereinto the wire 96′. Thus, the direct light can be effectively prevented from being directed into and absorbed in the through hole 97, thereby increasing the radiation light intensity. Further, the light-emitting element 95 is, at its entire lower surface, joined to the mounting portion 92b of the reflection member 92, whereby making it possible to transmit the heat emanating from the light-emitting element 95 to the reflection member 92 satisfactorily and thereby improve the heat-dissipation property.

Note that the depth of the through hole 97 (i.e., the thickness of the bottom portion of the reflection member 92) and the opening diameter of the through hole 97 are appropriately determined in consideration of the difference in thermal expansion between the reflection member 92 and the base body 91, the conductivity for heat emanating from the light-emitting element 95, and other factors. Also in the case of FIG. 17, the thickness of the bottom portion of the reflection member 92 is appropriately determined.

Furthermore, it is possible to effectively suppress that light leaks through the through hole 97 for inserting the wire 96′ therethrough which through hole is formed in the reflection member 92 and is absorbed into the base body 91, by setting the average particle diameter of the crystal grains contained in ceramics to a range of 1 to 5 μm to improve the reflectivity of the base body 91.

As the light-emitting apparatus 90C according to a thirteenth embodiment of the invention shown in FIG. 20, the through hole 97 is preferably filled with an insulative paste 97a containing insulative light-reflecting particles in such a way as to be flush with the upper principal surface of the reflection member 92. In this way, even though the light emitted from the light-emitting element 95 and the fluorescent materials 94 is directed into the through hole 97, the light can be effectively reflected upward from the light-reflecting particles. Thus, in the light-emitting apparatus, satisfactory optical characteristics such as on axis luminous intensity, brightness, and color rendering can be attained.

It is preferable that the insulative paste 97a contains light-reflecting particles having a composition of barium sulfate, calcium carbonate, alumina, silica, etc. added with Ca, Ti, Ba, Al, Si, Mg, K, and O, and that the total reflectivity on the surface is adjusted to be 80% or more. This makes it possible to attain satisfactory optical characteristics such as on-axis luminous intensity, brightness, and color rendering in the light-emitting apparatus.

The light-transmitting member 93 is made of light-transmitting resin such as epoxy resin or silicone resin, or glass containing the fluorescent materials 94 capable of performing wavelength conversion on the light emitted from the light-emitting element 95. The light-transmitting member 93 is formed by charging the material inside the reflection member 92 by an injector such as a dispenser so as to cover the light-emitting element 95, followed by performing heat-hardening thereon in an oven or the like equipment. Thus, it is possible to take out light having a desired wavelength spectrum by subjecting the light emitted from the light-emitting element 95 to wavelength conversion effected by the fluorescent materials 94.

Moreover, the light-transmitting member 93 is so disposed that an interval X between its upper surface and the light-emitting section of the light-emitting element 95 ranges from 0.1 to 0.5 mm. In this way, the light emitted from the light-emitting element 95 can be wavelength-converted with high efficiency by the fluorescent materials 94 contained in a part of the light-transmitting member 93 of predetermined thickness which part is located above the light-emitting section of the light-emitting element 95, and then the wavelength-converted light is allowed to exit directly from the light-transmitting member 93 without suffering from disturbance caused by the fluorescent materials 94. As a result, the light-emitting apparatus is capable of providing increased radiation intensity and excellent optical characteristics such as on-axis luminous intensity, brightness, and color rendering.

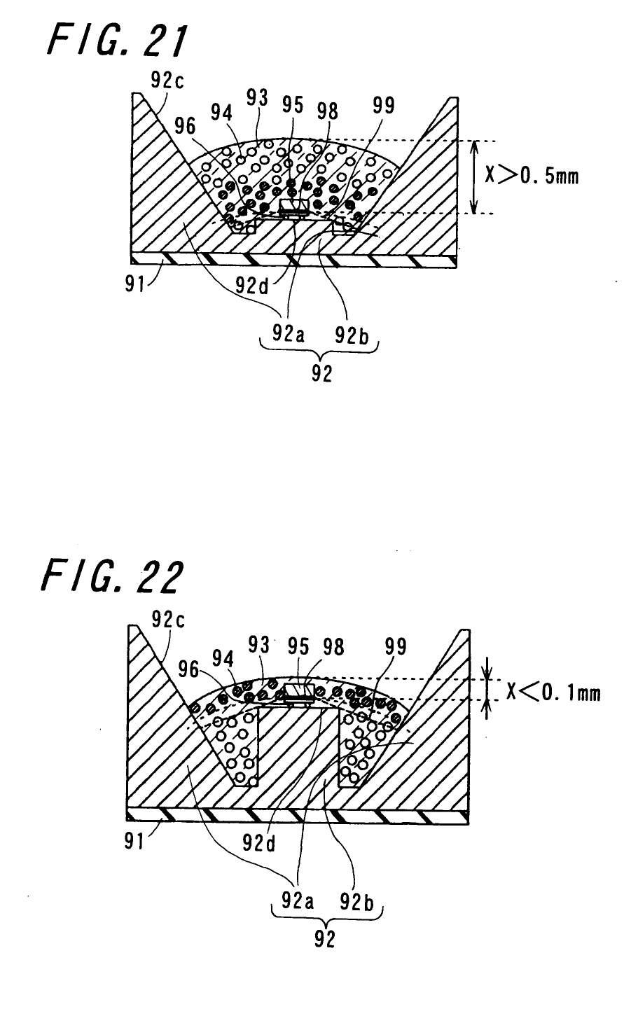

It the interval between the light-emitting section of the light-emitting element 95 and the surface of the light-transmitting member 93 is longer than 0.5 mm as shown in FIG. 21, although, of the fluorescent materials 94, the ones existing closer to the light-emitting element 95 (hatched fluorescent materials 94 in FIG. 21) are capable of effecting wavelength conversion through direct excitation of light emitted from the light emitting element 95, it is difficult to allow the wavelength-converted light to exit directly from the light transmitting member 93. That is, since the travel of light is disturbed by the fluorescent materials 94 existing near the surface of the light-transmitting member 93 (the ones other than the hatched fluorescent materials 94), it will become difficult to attain satisfactory external on-axis luminous intensity.

By contrast, as shown in FIG. 22 if the interval X between the light-emitting section of the light-emitting element 95 and the surface of the light-transmitting member 93 is shorter than 0.1 mm, it will be difficult to achieve efficient wavelength conversion for the light emitted from the light-emitting element 95. In this case, there is an undesirable increase in the quantity of low-luminosity light of certain wavelength that is transmitted through the light-transmitting member 93 without undergoing wavelength conversion, with the result that satisfactory optical characteristics such as on-axis luminous intensity, brightness, and color rendering cannot be attained.

Moreover, as shown in FIG. 17, the upper surface of the light-transmitting member 93 is preferably so shaped as to rise convexly. In this way, the interval between the light-emitting section and the surface of the light-transmitting member 93 can be kept in a range from 0.1 to 0.5 mm. Thus, even if light is emitted obliquely upwardly from the light-emitting element 95, the radiation intensity can be increased.

In order for the light-emitting apparatus 41, 50, 60, 60A, 60B, 60C, 60D, 70, 80, 90, 90A, 90B and 90C embodying the invention to constitute an illumination apparatus, a few ways will be considered, i.e. setting up a single piece of the light-emitting apparatus 41, 50, 60, 60A, 60B, 60C, 60D, 70, 80, 90, 90A, 90B and 90C in a predetermined arrangement; setting up a plurality of light-emitting apparatuses 41, 50, 60, 60A, 60B, 60C, 60D, 70, 80, 90, 90A, 90B and 90C in a lattice, staggered, or radial arrangement; and setting up a plurality of concentrically-arranged circular or polygonal light-emitting apparatus 41, 50, 60, 60A, 60B, 60C, 60D, 70, 80, 90, 90A, 90B and 90C units composed of a plurality of light-emitting apparatus 41, 50, 60, 60A, 60B, 60C, 60D, 70, 80, 90, 90A, 90B and 90C in a predetermined arrangement. In the illumination apparatus thus constructed, light emission is effected by exploiting recombination of electrons in the light-emitting elements 44, 55, 65, 75, 85 and 95 composed of a semiconductor. Thus, the illumination apparatus has the advantage, in terms of power saving and long lifetime, over a conventional illumination apparatus for effecting light emission through electrical discharge. A compact, low heat-generation illumination apparatus can accordingly be realized. As a result, variation in the center wavelength of the light emitted from the light-emitting element 44, 55, 65, 75, 85 and 95 can be suppressed; wherefore the illumination apparatus will succeed in irradiating light with stable radiation light intensity and angle (luminous intensity distribution) for a longer period of time, and in avoiding color unevenness and unbalanced illumination distribution on a to-be-irradiated surface.

Moreover, by setting up the light-emitting apparatuses 41, 50, 60, 60A, 60B, 60C, 60D, 70, 80, 90, 90A, 90B and 90C of the invention as a light source in a predetermined arrangement, followed by arranging around the light-emitting apparatus 41, 50, 60, 60A, 60B, 60C, 60D, 70, 80, 90, 90A, 90B and 90C an optical component optically designed in a given configuration such as a reflection jig, an optical lens, or a light diffusion plate, it is possible to realize an illumination apparatus capable of emitting lights with given luminous intensity distribution.

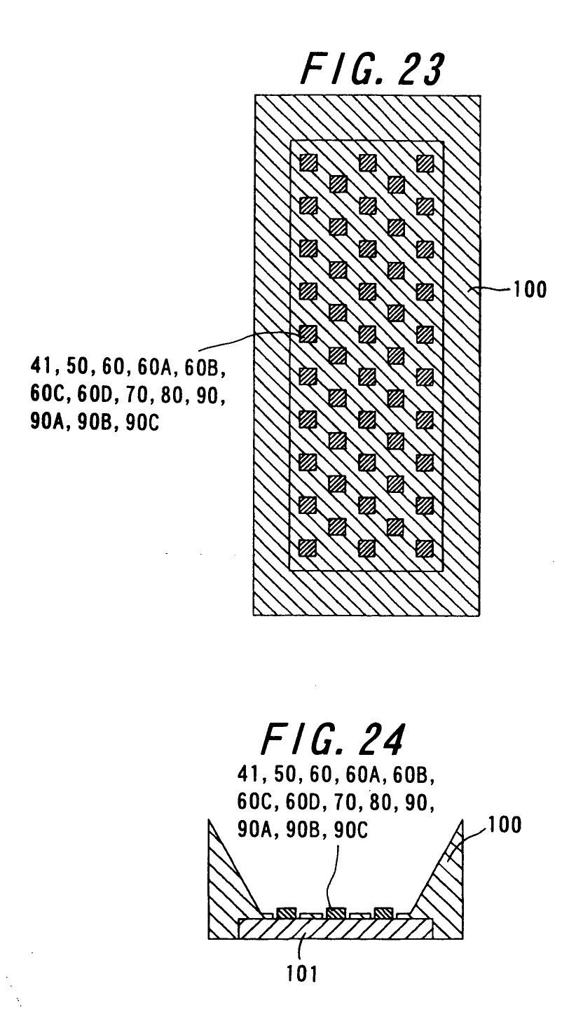

For example, FIGS. 23 and 24 show a plan view and a sectional view, respectively, of an illumination apparatus composed of a plurality of light-emitting apparatuses 41, 50, 60, 60A, 60B, 60C, 60D, 70, 80, 90, 90A, 90B and 90C arranged in rows and columns on a light-emitting apparatus drive circuit board 101; and a reflection jig 100 optically designed in a given configuration, which is disposed around the light-emitting apparatus 41, 50, 60, 60A, 60B, 60C, 60D, 70, 80, 90, 90A, 90B and 90C. In this construction, adjacent arrays of a plurality of light-emitting apparatuses 41, 50, 60, 60A, 60B, 60C, 60D, 70, 80, 90, 90A, 90B and 90C are preferably so arranged as to secure as sufficient a spacing as possible between the adjacent light-emitting apparatuses 41, 50, 60, 60A, 60B, 60C, 60D, 70, 80, 90, 90A, 90B and 90C, that is; the light emitting apparatuses 41, 50, 60, 60A, 60B, 60C, 60D, 70, 80, 90, 90A, 90B and 90C are staggered. If the light-emitting apparatuses 41, 50, 60, 60A, 60B, 60C, 60D, 70, 80, 90, 90A, 90B and 90C are disposed in a lattice arrangement, that is; the light-emitting apparatuses 41, 50, 60, 60A, 60B, 60C, 60D, 70, 80, 90, 90A, 90B and 90C acting as light sources are arranged rectilinearly, glare will be intensified. An illumination apparatus having such a lattice arrangement of the light-emitting apparatuses 41, 50, 60, 60A, 60B, 60C, 60D, 70, 80, 90, 90A, 90B and 90C tends to bring discomfort or trouble to human eyes. In view of the foregoing, by adopting the staggered arrangement, it is possible to suppress glare and thereby reduce discomfort or trouble to human eyes. Another advantage is that, since the spacing between the adjacent light-emitting apparatuses 41, 50, 60, 60A, 60B, 60C, 60D, 70, 80, 90, 90A, 90B and 90C can be kept as long as possible, it will be possible to effectively suppress thermal interference between the adjacent light-emitting apparatuses 41, 50, 60, 60A, 60B, 60C, 60D, 70, 80, 90, 90A, 90B and 90C. Hence, heat confinement within the light-emitting apparatus drive circuit board 101 carrying the light-emitting apparatuses 41, 50, 60, 60A, 60B, 60C, 60D, 70, 80, 90, 90A, 90B and 90C can be avoided; wherefore heat can be dissipated to the outside through the light emitting apparatuses 41, 50, 60, 60A, 60B, 60C, 60D, 70, 80, 90, 90A, 90B and 90C with high efficiency. As a result, there will be provided a long-life illumination apparatus that has little adverse effect on human eyes and offers stable optical characteristics for a longer period of time.

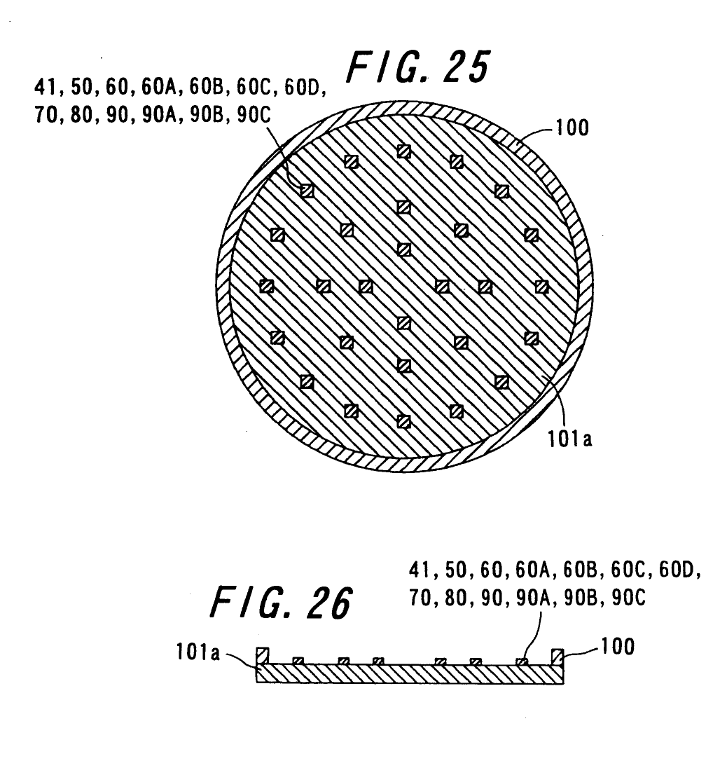

On the other hand, FIGS. 25 and 26 show a plan view and a sectional view, respectively, of another illumination apparatus constituted by disposing, on the light emitting apparatus drive circuit board 101a, a plurality of concentrically-arranged circular or polygonal light-emitting apparatuses 41, 50, 60, 60A, 60B, 60C, 60D, 70, 80, 90, 90A, 90B and 90C units composed of a plurality of light-emitting apparatuses 41, 50, 60, 60A, 60B, 60C, 60D, 70, 80, 90, 90A, 90B and 90C. In this construction, it is preferable that, in a single circular or polygonal light-emitting apparatuses 41, 50, 60, 60A, 60B, 60C, 60D, 70, 80, 90, 90A, 90B and 90C unit, the light-emitting apparatuses 41, 50, 60, 60A, 60B, 60C, 60D, 70, 80, 90, 90A, 90B and 90C are so arranged that the number thereof becomes larger gradually from the center to the outer edge of the illumination apparatus. This makes it possible to arrange the light-emitting apparatuses 41, 50, 60, 60A, 60B, 60C, 60D, 70, 80, 90, 90A, 90B and 90C as many as possible, with the spacing between the adjacent light-emitting apparatuses 41, 50, 60, 60A, 60B, 60C, 60D, 70, 80, 90, 90A, 90B and 90C secured appropriately, and thereby enhance the light level of the illumination apparatus. Moreover, since the density of the light-emitting apparatuses 41, 50, 60, 60A, 60B, 60C, 60D, 70, 80, 90, 90A, 90B and 90C is lowered in a center portion of the illumination apparatus, it will be possible to avoid heat confinement in the center portion of the light-emitting apparatus drive circuit board 101a. Hence, the light emitting apparatus drive circuit board 101a exhibits uniform temperature distribution, and thus heat can be transmitted to an external electric circuit board with the illumination apparatus or a heat sink with high efficiency, thereby preventing temperature rise from occurring in the light-emitting apparatuses 41, 50, 60, 60A, 60B, 60C, 60D, 70, 80, 90, 90A, 90B and 90C. As a result, there will be provided a long-life illumination apparatus in which the light-emitting apparatuses 41, 50, 60, 60A, 60B, 60C, 60D, 70, 80, 90, 90A, 90B and 90C can be operated with stability for a longer period of time.

The illumination apparatus such as shown herein will find a wider range of applications including: general-purpose lighting fixtures for indoor or outdoor use: illumination lamps for chandeliers; home-use lighting fixtures; office-use lighting fixtures; store use lighting fixtures; lighting fixtures for display; street lighting fittings; guidance lights; signal devices; lighting fixtures for stage or studio use; advertisement lights; illumination poles; underwater illumination lights; stroboscopic lights; spotlights; security lighting fixtures embedded in electric poles or the like; lighting fixtures for emergency; electric torches; electric bulletin boards; dimmers; automatic blink switches; backlights for display or other purposes; motion picture devices; ornamental articles; illuminated switches; light sensors; lights for medical use; and vehicle-mounted lights.

### IMPLEMENTED EXAMPLE

### Example 1

Hereinafter, a description will be given as to an implemented example of the light-emitting apparatus 41 according to the first embodiment of the invention.

At first, as the base body 42, an alumina ceramic substrate made of crystalline particles having different diameters was prepared. Then, around the mounting portion 42a for mounting thereon the light-emitting element 44 was formed a wiring conductor for electrically connecting the light-emitting element 44 to the external electric circuit board through an internal wiring line formed within the base body 42. Note that the wiring conductor formed on the upper surface of the base body 42 was shaped into a 0.1 mm-diameter circular pad with use of a metallized layer made of Mo—Mn powder. The wiring conductor has its surface coated with a 3 μm-thick Ni plating layer and a 2 μm thick Au plating layer successively. Moreover, the internal wiring line formed within the base body 42 was constituted by an electrical connection portion formed of a through conductor, i.e. so-called through hole. Alike to the wiring conductor, the through hole was also formed of a metallized layer made of Mo—Mn powder.

Subsequently, a 0.08 mm-thick light-emitting element 44 for emitting near-ultraviolet light was attached to the mounting portion 42a with use of an Ag paste, and then the light-emitting element 44 was electrically connected to the wiring conductor through a bonding wire made of Au.

Next, silicone resin (light-transmitting member 45) was applied so as to cover the light-emitting element 44 by a dispenser, followed by performing heat-hardening thereon. The silicone resin contains fluorescent materials that emit yellow light after being excited by the light emitted from the light-emitting element 44. Whereupon, a sample of the light emitting apparatus 41 was fabricated. Then, the optical power of the sample was measured.

In the silicone resin, the fluorescent materials were uniformly dispersed at a filling factor of ¼ (mass %). The fluorescent materials in use were yttrium aluminate-based fluorescent materials having a garnet conformation for emitting yellow light. The grains of the fluorescent materials range in average particle diameter from 1.5 μm to 80 μm.

When the average particle diameter of the ceramic crystal grains constituting the base body 42 was set at approximately 10 μm, the optical power was found to be 14 mW. By contrast, when the average particle diameter of the ceramic crystal grains constituting the base body 42 was adjusted to fall in a range from 1 to 5 μm, the optical power was found to be 17 mW. As will be understood from this fact, as compared with the case of setting the average particle diameter at approximately 10 μm, the optical power energy was increased by greater than 20%. That is, by designing the base body such that the ceramic crystal's average particle diameter falls in a range from 1 to 5 μm, it is possible to cut off light that finds its way into the base body 42 more effectively, and to increase the number of fluorescent materials subjected to light irradiation resulting from light dispersion occurring on the surface of the base body 42. The optical power was enhanced in this way.

It has also been confirmed that, when the amperage was increased to enhance the optical power of the light-emitting apparatus 41, with the base body having a ceramic average particle diameter ranging from 1 to 5 μm, an undesirable decrease in the light emission efficiency with respect to a forward current can be avoided more effectively.

### Example 2

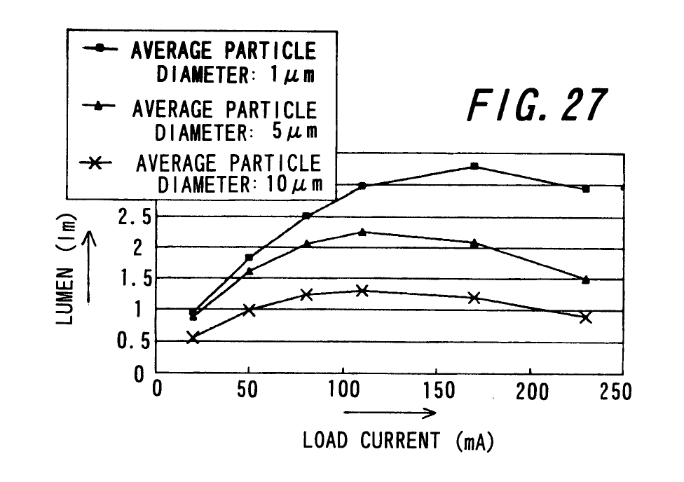

Next, samples of the light-emitting apparatus 41 were fabricated. The samples, of which each has the same structure as that of the above-stated implemented example, are identical in structure with one another, but differ from one another in an average particle diameter of the ceramic crystal grains as observed after the sintering of the base body 42:1 (μm); 5 (μm); and 10 (μm). Then, the total light beams (optical power) with respect to the load current for the light-emitting element 44 were measured. Note that the light-emitting apparatuses 41 were individually mounted in heat sinks that are identical in cooling capability with one another. The optical power was measured by means of integrating sphere. The results are listed in FIG. 27.

As will be understood from FIG. 27, given the load current for the light-emitting element 44 of 20 (mA), i.e. rated current and rated voltage of 3.4 (V), then the light-emitting apparatus 41 having the average particle diameter of the ceramic crystal grains of 1 (μm) exhibited optical power of 0.96 (lm) and light emission efficiency of 14 (lm/W), whereas the light-emitting apparatus 41 having the average particle diameter of the ceramic crystal grains of 5 (μm) exhibited optical power of 0.8 (lm) and light emission efficiency of 12 (lm/W). By contrast, the light-emitting apparatus 41 having the average particle diameter of ceramic crystal grains of 10 (μm) exhibited optical power of 0.55 (lm) and light emission efficiency of 8 (lm/W). That is, at the rated current, the optical power of the light-emitting apparatus 41 having the average particle diameter of the ceramic crystal grains of 1 (μm) to 5 (μm) was increased by 45 to 74% relative to the optical power of the light-emitting apparatus 41 in which the average particle diameter of the ceramic crystal grains constituting the base body 42 is set at 10 (μm).

Specifically, by designing the base body 42 such that the average particle diameter of the ceramic crystal grains falls in a range from 1 to 5 (μm), it is possible to effectively cut off light that finds its way into the base body 42. In addition, with the asperities created on the surface of the base body 42 by the crystal grains, the light emitted from the light-emitting element 44 can be reflected in a substantially totally dispersed state. Hence, the fluorescent materials contained within the frame body 43 are irradiated with uniform light intensity, and also the number of fluorescent materials subjected to light irradiation is increased. This helps increase the probability of occurrence of fluorescent materials to be excited by the light emitted from the light emitting element 44, thereby improving the light conversion efficiency of the fluorescent materials. As a result, in the light-emitting apparatus 41 in which the average particle diameter of the ceramic crystal grains constituting the base body 42 is adjusted to fall in a range from 1 to 5 (μm), its light emission efficiency is equal to or greater than the light emission efficiency of an incandescent lamp, i.e. 12 (lm/W). The light-emitting apparatus 41 can accordingly be put to practical use as a display or illumination light source.

Moreover, when the load current was increased to enhance the optical power of the light-emitting apparatus 41, the following results were observed. In the case where the average particle diameter of the ceramic crystal grains constituting the base body 42 was large, the increase of the optical power proportional to the load current topped out at an amperage of approximately 100 (mA) or below. By contrast, in the case where the ceramic crystal's average particle diameter was small, the optical power continued to rise in proportion to the increase of the amperage until it reached a certain higher level. In particular, in the case where the average particle diameter was set at 1 μm, the optical power of the light-emitting apparatus 41 continued to rise proportionally until the amperage reached approximately 110 mA. That is, by reducing the average particle diameter of the ceramic crystal grains constituting the base body 42, it is possible to improve the heat-dissipation property within the base body 42, and thereby suppress temperature rise caused by the load current in the light-emitting element 44 and suppress the deterioration of light emission efficiency of the light-emitting element.

Further, samples of the light-emitting apparatus 41 with varying average particle diameters or ceramic crystal grains were fabricated, and measurement was made on each of them as to the peak wavelength of the light-emitting element 44 with respect to the load current in the light-emitting apparatus 41. As a consequence, it has been confirmed that variation in the peak wavelength of the light-emitting element 44 can be minimized by setting the average particle diameter of the ceramic crystal grains constituting the base body 42 at 1 μm. In this way, variation in the conversion efficiency of the fluorescent materials dependent upon the peak wavelength of the light-emitting element 44 can be minimized. Moreover, in a case where the light-emitting apparatus 41 includes a plurality of fluorescent materials having different excitation spectrums, variation in the conversion efficiency of the fluorescent materials resulting from variation in the peak wavelength of the light-emitting element 44 can be minimized. As a result, it is possible to minimize variation in the color of light that has been outputted from the light-emitting apparatus 41 as a mixture of light components excited by a plurality of fluorescent materials. For example, assuming that the fluorescent materials are composed of red color phosphors, blue-color phosphors, and green-color phosphors, and that the peak wavelength of the light-emitting element 44 varies with load current. In this case, the light emission intensities of the red-color, blue-color, and green color phosphors will vary with the peak wavelength of the light-emitting element 44 at their own characteristics. If the light-emitting apparatus puts out light in this state, since the proportion of light intensity in a mixture of light components excited by the red-color, blue-color, and green-color phosphors is varied, it follows that the color tone of the outputted light is varied undesirably. This makes it impossible to obtain light having a desired color tone. Hence, by setting the average particle diameter of the ceramic crystal grains constituting the base body 42 at 1 μm, variation in the peak wavelength of the light-emitting element 44 can be minimized, and correspondingly variation in the color tone of the outputted light can be minimized. This makes it possible to produce a light-emitting apparatus having stable light-emission and illumination characteristics that is suitable for use in a display or illumination purposes.

### Example 3

Hereinafter, an implemented example of the light-emitting apparatus 60c according to the sixth embodiment of the invention will be described with reference to FIG. 7.

At first, as the base body 61, an alumina ceramic substrate was prepared. Note that the base body 61 has the convexity 61b with a mounting portion 61a formed integrally therewith. The upper surface of the mounting portion 61A and the upper surface of the base body 61 excluding a part of the mounting portion 61a were arranged parallel to each other.

The base body 61 is composed of a cylindrically-shaped plate of 0.8 mm in diameter and 0.5 mm in thickness and a cylindrically-shaped convexity 61b of 0.4 mm in diameter and any given value in thickness. The convexity 61b if formed at the center of the upper surface of the cylindrically-shaped plate.

The convexity 61b includes the mounting portion 61a for mounting thereon the light-emitting element 65. Formed on the mounting portion 61a is an electrical connection pattern for electrically connecting the light-emitting element 65 to the external electric circuit board through an internal wiring line formed within the base body 61. The electrical connection pattern was shaped into a 0.1 mm-diameter circular pad with use of a metallized layer made of Mo—Mn powder. The electrical connection pattern has its surface coated with a 3 μm-thick Ni plating layer and a 2 μm-thick Au plating layer successively. The internal wiring line formed within the base body 61 was constituted by an electrical connection portion formed of a through conductor, i.e. so-called through hole. Alike to the electrical connection pattern, the through hole was also formed of a metallized layer made of Mo—Mn powder.

Moreover, the base body 61 has, on its entire upper surface excluding the part of the convexity 61b, a joint portion for bonding together the base body 61 and the reflection member 62 with use of Au-tin (Sn) brazing filler. The joint portion was formed by coating the surface of a metallized layer made or Mo—Mn powder with a 3 μm-thick Ni plating layer and a 2 μm-thick Au plating layer.

Further, the reflection member 62 was prepared. The reflection member 62 includes a through hole 62a having a rectangular inner peripheral surface when viewed in the vertical section shown in FIG. 7. The top of the inner peripheral surface of the through hole 62a was shaped into a reflection surface 62b whose Ra was set at 0.1 μm.

In addition, the reflection member 62 was cylindrically shaped, the dimensions of which: 0.8 mm in exterior diameter; 1.0 mm in height; 0.8 mm in diameter of upper opening; 0.5 mm in diameter of lower opening; and 0.15 mm in height of reflection surface 62b's lower end 62c (thickness L of a part of the reflection member 62 which lies around the lower opening).

Next, an Au—Sn bump (electrode 66) was disposed in the 0.08 mm-thick light-emitting element 65 for emitting near-ultraviolet light. Through the Au—Sn bump, the light-emitting element 65 was joined to the electrical connection pattern. Concurrently, the reflection member 62 was joined to the joint portion formed on the upper surface of the base body 61 with use of Au—Sn brazing filler. The level of the light-emitting section of the light-emitting element 65 with respect to the lower surface of the Au—Sn bump, namely, the interval from the mounting portion 61a to the light-emitting section, was set at approximately 0.03 mm.

Next, silicone resin (light-transmitting member 63) was charged into the area surrounded by the base body 61 and the reflection member 62 by a dispenser, until the level of the silicone resin reached the uppermost end of the inner peripheral surface of the reflection member 62. The silicone resin contains fluorescent materials 64 of three different types that emit red light, green light, and yellow light individually. Whereupon, a sample of the light-emitting apparatus was fabricated.

Then, by varying the value representing the thickness of the convexity 61b, the height H (mm) of the light-emitting section of the light-emitting element 65 as seen from the base body 61 was varied (H is defined by the sum of the thickness of the convexity 61b and the level of the light-emitting section with respect to the mounting portion 61a: 0.03 mm). Note that the interval X (mm) between the light-emitting section of the light-emitting element 65 and the upper surface of the light-transmitting member 63 can be represented by a value obtained by subtracting H (mm) from the interval between the upper surface of the light-transmitting member 63 and the base body 61: 1.0 mm.

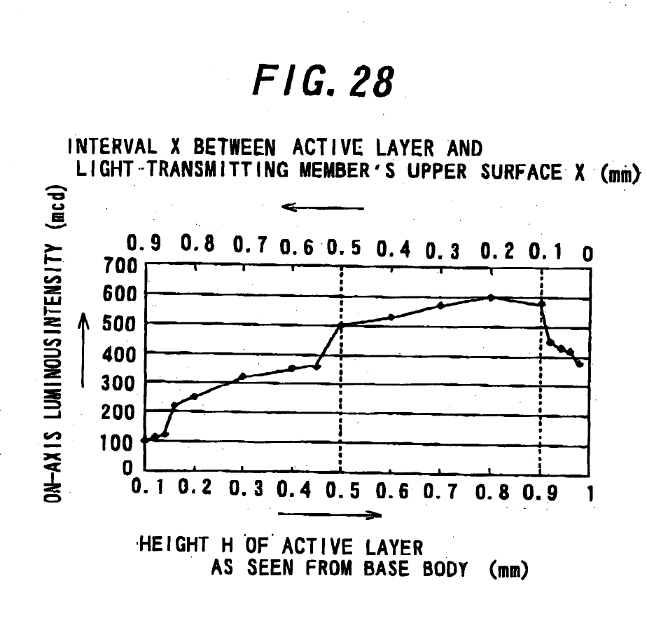

FIG. 28 is a graph showing the result of on-axis luminous intensity measurement made on each sample on the basis of the values H and X. As will be understood from the graph, given H of 0.1˜0.15 mm (the height of the light-emitting section is equal to or less than the height of the reflection surface 62b's lower end 62c: 0.15 mm), then the on-axis luminous intensity is low. By contrast, given H of 0.16 mm or above (the height of the light-emitting section is greater than the height of the reflection surface 62b's lower end 62c: 0.15 mm), then the on-axis luminous intensity is extremely high. This is because, by making the light-emitting section higher than the reflection surface 62b's lower end 62c, the light emitted from the light-emitting element 65 can be reflected from the reflection surface 62b satisfactorily, which results in the reflection efficiency being increased.

As H is increased even further, the on-axis luminous intensity becomes higher and higher gently. Here, it has been confirmed that the on-axis luminous intensity is sharply heightened when X takes on a value ranging from 0.1 to 0.5 mm. As the reason therefor, it can be considered that, by adjusting the interval between the light-emitting section and the upper surface of the light-transmitting member 63 appropriately, the light emitted from the light-emitting element 65 can be wavelength-converted by the fluorescent materials 64 with higher efficiency, and the wavelength converted light is allowed to exit highly efficiently from the light-transmitting member 63 without suffering from disturbance caused by needless fluorescent materials 64. It has also been confirmed that such a sample as that which exhibits remarkably high on-axis luminous intensity offers sufficiently high brightness, color rendering, etc.

### Example 4

Hereinafter, an implemented example of the light-emitting apparatus 90B according to the twelfth embodiment of the invention will be described with reference to FIGS. 19, 29, and 30.

At first, as the base body 91, there was prepared an alumina ceramic substrate made of a rectangular plate having an outer dimension of 2.5 mm×0.8 mm and a thickness of 0.4 mm. In addition, the reflection member 92 was prepared by using an Al-made rectangular member having an outer dimension of 2.5 mm×0.8 mm. The reflection member 92 has, at the center of its upper principal surface, a cylindrically-shaped mounting portion 92b having a diameter of L (mm). The thickness of that part of the reflection member 92 which lies around the mounting portion 92b (the interval between the upper and lower surface thereof) is set 0.2 mm. The reflection member 92 also has, at its outer periphery, a frame-like side wall portion 92a which is 1.0 mm in height as seen from the lower principal surface (protrudes by 0.8 mm from the lower principal surface) and 0.2 mm in lateral thickness. Note that the side wall portion 92a has its inner peripheral surface perpendicular to the base body 91 shaped into a reflection surface 92c whose arithmetic average roughness Ra was set at 0.1 μm.

Moreover, a single through hole 97 was created on both sides of the mounting portion 92b, specifically, created both in the part between the mounting portion 92b and one side of the side wall portion 92a and in the part between the mounting portion 92b and the other side of the side wall portion 92a, in the direction of the longer side of the reflection member 92 that is rectangular-shaped, as viewed top-wise. The through hole 97 was drilled all the way through from the upper principal surface to the lower principal surface of the reflection member 92.

Next, an electrode, which is part of the wiring conductor, was formed on that part of the upper surface of the base body 91 which faces with the bottom of the through hole 97. The electrode was shaped like a circle having a diameter of 0.1 mm with use of a metallized layer made of Mo—Mn powder. The electrode has its surface coated with a 3 μm-thick Ni plating layer and a 2 μm thick Au plating layer successively. The wiring conductor formed within the base body 91 was constituted by an electrical connection portion formed of through conductor, i.e. so-called through hole. Alike to the electrical connection pattern, the through hole was also formed of a metallized layer made of Mo—Mn powder.

Moreover, in the base body 91, at the outer periphery of its upper surface was formed entirely circumferentially a joint portion for bonding together the base body 91 and the reflection member 92 with use of Au-tin (Sn) brazing filler. The joint portion was formed by coating the surface of a metallized layer made of Mo—Mn powder with a 3 μm-thick Ni plating layer and a 2 μm-thick Au plating layer.

Next, onto the upper surface 92d of the mounting portion 92b was bonded the 0.08 mm-thick light-emitting element 95 for emitting near-ultraviolet light with use of Au—Sn brazing filler. Concurrently, the reflection member 92 was joined to the joint portion formed on the upper surface of the base body 91 with use of Au—Sn brazing filler. Further, the light-emitting element 95 and the electrode located at the bottom of the through hole 97 were wire-bonded and electrically connected to each other by a gold wire.

Thence, silicone resin (light-transmitting member 93) was charged into the area surrounded by the base body 91 and the reflection member 92 by a dispenser, until the level of the silicone resin reached the uppermost end of the inner peripheral surface of the reflection member 92. The silicone resin contains fluorescent materials 94 of three different types that emit red light, green light, and yellow light individually. Whereupon, a sample of the light-emitting apparatus 90B was fabricated.

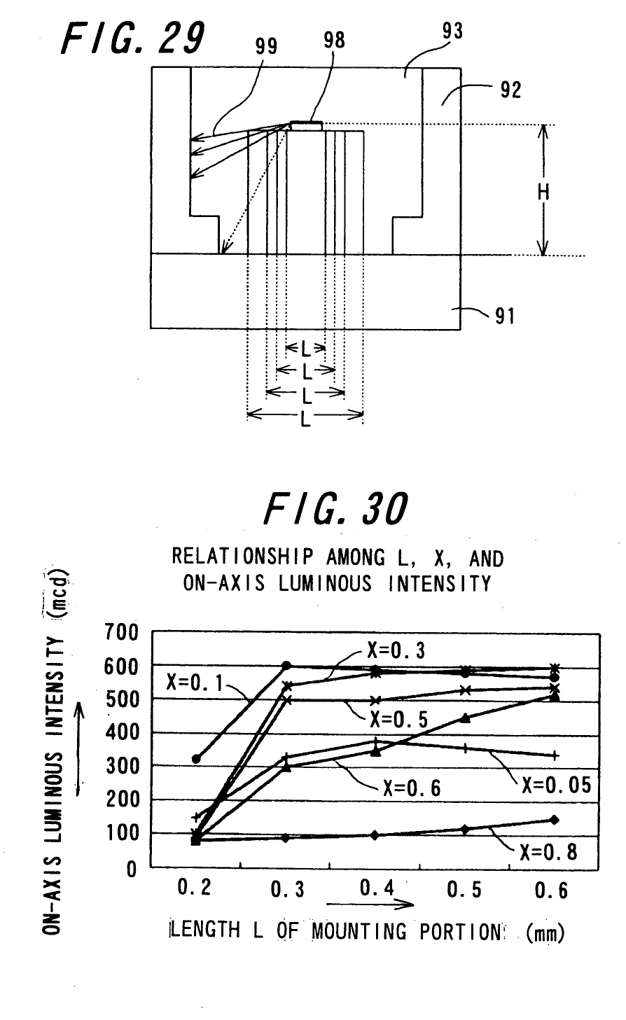

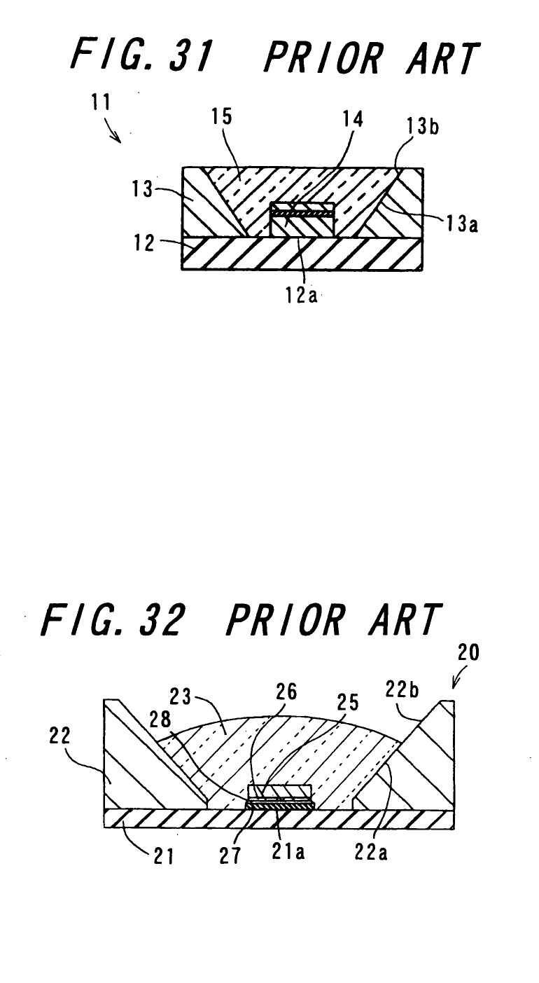

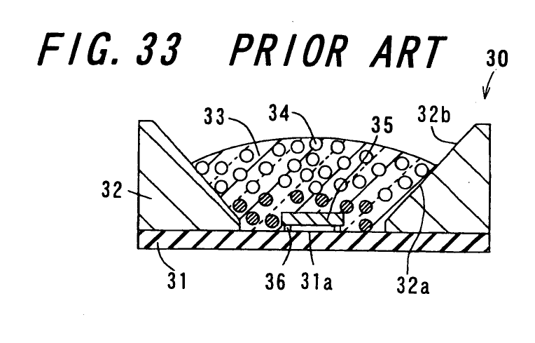

The value representing the height H (mm) of the light-emitting section of the light-emitting element 95 as seen from the base body 91 can be widely varied by varying the height of the mounting portion 92b. The interval X (mm) between the upper surface of the light-transmitting member 93 and the light-emitting section is given by: X−1.0−H. Moreover, as shown in FIG. 29, by varying the diameter L of the mounting portion 92b, it is possible to change the angle of the optical path line 99 connecting the light-emitting section and the corner between the upper surface 92d and the side surface of the mounting portion 92b.

FIG. 30 is a graph showing the result of on-axis luminous intensity measurement made on each sample on the basis of the values L and X. As will be understood from the graph, fluctuations in the on-axis luminous intensity are dependent upon the relationship between L and X. That is, given L of less than 0.3 mm, then the optical path line 99 lies below a line connecting the light-emitting section 98 and the lower end of the reflection surface 92c. It can thus be considered that the reflection efficiency was lowered because of the direct light emitted from the light-emitting element 95 finding its way into the through hole 97 without entering the reflection surface 92c.

By contrast, given L of 0.3 mm or above, then the optical path line 99 lies above the line connecting the light-emitting section 98 and the lower end of the reflection surface 92c. In this case, that is, when direct light was not incident upon the through hole 97, the on-axis luminous intensity was found to be as high as 500 mcd or above provided that X takes on a value ranging from 0.1 to 0.5 mm. As the reason therefor, it can be considered that, by adjusting the interval X between the light-emitting section 98 and the upper surface of the light-transmitting member 93 appropriately, the light emitted from the light-emitting element 95 can be wavelength-converted by the fluorescent materials 94 with higher efficiency, and the wavelength-converted light is allowed to exit highly efficiently from the light-transmitting member 93 without suffering from disturbance caused by needless fluorescent materials 94.

As will be understood from the foregoing results, excellent on-axis luminous intensity can be attained under the conditions that the lower end of the reflection surface 92c is located on or below the optical path line connecting the light-emitting section 98 and the corner between the upper surface 92d and the side surface of the mounting portion 92b, and that the interval between the light-emitting section 98 and the upper surface of the light-transmitting member 93 is kept in a range from 0.1 to 0.5 mm. It has also been confirmed that such a sample as that which exhibits remarkably high on-axis luminous intensity offers sufficiently high brightness, color rendering, etc.

It is to be understood that the application of the invention is not limited to the first to thirteenth embodiments described heretofore, and that many modifications and variations of the invention are possible within the spirit and scope of the invention. In the first embodiment of the invention, for example, an optical lens or a platy light-transmitting lid may additionally be bonded to the upper surface of the frame body 43 with use of solder or an adhesive. In this case, since the optical lens or platy light-transmitting lid is capable of condensing or diffusing light emitted from the light-emitting apparatus 41 freely, it will be possible to take out light at a desired angle and to improve the immersion resistance inside the light-emitting apparatus 41, which leads to enhancement of long-term reliability. Moreover, the inner peripheral surface of the frame body 43 may be so shaped as to have a flat (rectilinear) sectional profile or a circular arc (curved) sectional profile. With the circular arc sectional profile, the light emitted from the light emitting element 44 can be reflected thoroughly and thus allowed to radiate out evenly with high directivity. Further, in the first to thirteenth embodiments of that invention, the base bodies 42, 51, 61, 71, 81 and 91 may be provided with a plurality of light-emitting elements 44, 55, 65, 75, 85 and 95 to enhance the optical power. In addition, the angle of the reflection surfaces 43b, 52b, 62b, 72b, 82b and 92c or the interval from the upper and of the reflection surfaces 43b, 52b, 62b, 72b, 82b and 92c to the upper surface of the light-transmitting members 45, 53, 63, 73, 83 and 93 may be adjusted arbitrarily. By doing so, complementary color regions can be secured; wherefore a more satisfactory color-rendering effect can be attained.

Note also that the illumination apparatus embodying the invention can be constituted by either setting up a plurality of light-emitting apparatuses 41, 50, 60, 60A, 60B, 60C, 60D, 70, 80, 90, 90A, 90B and 90C in a predetermined arrangement or setting up a single piece of the light-emitting apparatus 41, 50, 60, 60A, 60B, 60C, 60D, 70, 80, 90, 90A, 90B and 90C in a predetermined arrangement.

The invention maybe embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

1. A package for housing a light-emitting element comprising:
a base body made of ceramics and having, on its upper surface, a mounting portion for mounting thereon a light-emitting element;
a frame body joined to an outer periphery of the upper surface of the base body so as to surround the mounting portion, an inner peripheral surface of which is shaped into a reflection surface for reflecting light emitted from the light-emitting element; and
a wiring conductor having its one end formed on the upper surface of the base body so as to be electrically connected to an electrode of the light-emitting element, and another end led out to a side or lower surface of the base body,
wherein the base body is so designed that crystal grains contained in the ceramics range in average particle diameter from 1 to 5 μm.

2. A light-emitting apparatus comprising:
the package of claim 1; and
a light-emitting element mounted on the mounting portion and electrically connected to the wiring conductor.

3. The light-emitting apparatus of claim 2, further comprising a light-transmitting member disposed inside the frame body so as to cover the light-emitting element, which contains fluorescent materials for performing wavelength conversion on light emitted from the light-emitting element.

4. The light-emitting apparatus of claim 3, wherein an interval between an upper surface of the light-transmitting member and an active layer of the light-emitting element is kept in a range from 0.1 to 0.8 mm.

5. The light-emitting apparatus of claim 2, wherein the one end of the wiring conductor is designed as a conductor layer to which the light-emitting element is electrically connected through a conductive adhesive, and a convexity made of an insulating material is formed around the conductor layer.

6. The light-emitting apparatus of claim 5, wherein the conductor layer is so configured that the conductor layer lies inwardly of an outer periphery of the light-emitting element.

7. The light-emitting apparatus of claim 5, wherein the convexity is so shaped that its side surfaces inclinedly extend outward gradually with increasing proximity to the base body.

8. The light-emitting apparatus of claim 2, wherein the one end of the wiring conductor is designed as a conductor layer to which the light-emitting element is electrically connected through a conductive adhesive, and a convexity is formed in a part of an upper surface of the conductor layer which part lies inwardly of an outer periphery of the light-emitting element.

9. The light-emitting apparatus of claim 2, wherein the mounting portion protrudes from the upper surface of the base body.

10. The light-emitting apparatus of claim 9, wherein the protruding mounting portion is so shaped that its side surfaces inclinedly extend outward gradually with increasing proximity to the base body.

11. The light-emitting apparatus of claim 3, wherein the mounting portion protrudes from the upper surface of the base body, an active layer of the light-emitting element is higher in level than a lower end of the reflection surface, and the light-transmitting member is so disposed that an interval between its upper surface and the active layer is kept in a range from 0.1 to 0.5 mm.

12. The light-emitting apparatus of claim 11, wherein the light-transmitting member is so designed that its center portion is larger in arithmetic average surface roughness than its outer peripheral portion.

13. The light-emitting apparatus of claim 2, wherein the mounting portion protrudes from the upper surface of the base body, and on an upper surface of the mounting portion is formed a conductor layer which is made of the one end of the wiring conductor and to which the light-emitting element is electrically connected through a conductive adhesive, and a convexity made of an insulating material is formed around the conductor layer.

14. The light-emitting apparatus of claim 13, wherein the conductor layer is so configured that the conductor layer lies inwardly of an outer periphery of the light-emitting element.

15. The light-emitting apparatus of claim 13, wherein the convexity is so shaped that its side surfaces inclinedly extend outward gradually with increasing proximity to the base body.

16. A light-emitting apparatus comprising:
a base body formed in a platy shape and made of ceramics;
a light-emitting element; and
a reflection member joined to an upper surface of the base body, which has, at a center of its upper principal surface, a convex mounting portion for mounting thereon the light-emitting element, and further has, at an outer periphery of its upper principal surface, a side wall portion formed so as to surround the mounting portion, an inner peripheral surface of which side wall portion is shaped into a reflection surface for reflecting light emitted from the light-emitting element,
wherein the base body is so designed that crystal grains contained in the ceramics range in average particle diameter from 1 to 5 μm.

17. The light-emitting apparatus of claim 16, further comprising a light-transmitting member disposed inside the side wall portion so as to cover the light-emitting element, which contains fluorescent materials for performing wavelength conversion on light emitted from the light-emitting element.

18. The light-emitting apparatus of claim 17, wherein the light-transmitting member is so disposed that an interval between its upper surface and the active layer is kept in a range from 0.1 to 0.5 mm.

19. The light-emitting apparatus of claim 16, wherein the mounting portion is formed in a convex shape.

20. The light-emitting apparatus of claim 16, wherein the base body has a wiring conductor formed so as to extend from its upper surface, to outer surface; the reflection member has, around the mounting portion, a through hole drilled all the way through from the upper principal surface to a lower principal surface thereof so as to lie below the optical path line; and an electrode of the light-emitting element and the wiring conductor formed on the upper surface of the base body are electrically connected to each other by means of a wire inserted through the through hole.

21. The light-emitting apparatus of claim 20, wherein the through hole is filled with an insulative paste containing insulative light-reflecting particles.

22. An illumination apparatus constructed by setting up the light-emitting apparatus of claim 2 in a predetermined arrangement.

23. An illumination apparatus constructed by setting up the light-emitting apparatus of claim 3 in a predetermined arrangement.

24. An illumination apparatus constructed by setting up the light-emitting apparatus of claim 16 in a predetermined arrangement.

25. An illumination apparatus constructed by setting up the light-emitting apparatus of claim 17 in a predetermined arrangement.
